(19) United States
(12) Patent Application Publication
(10) Pub. No.: US 2022/0359970 A1
(43) Pub. Date: Nov. 10, 2022

(54) COUPLER WITH SWITCHABLE ELEMENTS

(71) Applicant: SKYWORKS SOLUTIONS, INC., Irvine, CA (US)

(72) Inventors: Sriram Srinivasan, Bedford, MA (US); Ujjwal Kumar, Woburn, MA (US); Nuttapong Srirattana, Lexington, MA (US); Zijiang Yang, Lexington, MA (US)

(21) Appl. No.: 17/661,935

(22) Filed: May 4, 2022

Related U.S. Application Data
(60) Provisional application No. 63/185,140, filed on May 6, 2021.
(60) Provisional application No. 63/185,120, filed on May 6, 2021.

(51) Int. Cl. H01P 5/16

(52) U.S. Cl. CPC H01P 5/16; H03K 17/56

(57) ABSTRACT

Examples of the disclosure include a coupler comprising an input port, an output port, a coupled port, an isolated port, a main line coupled between the input port and the output port, a coupled line coupled between the coupled port and the isolated port, and at least one capacitive element switchably coupled between at least one of the input port or the main line and at least one of the coupled port or the coupled line.

### CROSS-REFERENCE TO RELATED APPLICATIONS

This application claims priority under 35 U.S.C. § 119(e) to U.S. Provisional Application Ser. No. 63/185,140, titled “COUPLER WITH SWITCHABLE ELEMENTS,” filed on May 6, 2021, and to U.S. Provisional Application Ser. No. 63/185,120, titled “COUPLER WITH SWITCHABLE DECOUPLED COMPONENTS,” filed on May 6, 2021, each of which is hereby incorporated by reference in its entirety.

### BACKGROUND

At least one example in accordance with the present disclosure relates generally to couplers. Couplers include an input port, an output port, a coupled port, and an isolated port. A main transmission line couples the input port to the output port. A coupled transmission line couples the coupled port to the isolated port. The main transmission line may be coupled to the coupled transmission line. Accordingly, a portion of a signal provided between the input port and the output port may be coupled to at least one of the coupled port or the isolated port.

### SUMMARY

According to aspects of the disclosure, a coupler is provided comprising an input port, an output port, a coupled port, an isolated port, a main line coupled between the input port and the output port, a coupled line coupled between the coupled port and the isolated port, and at least one capacitive element switchably coupled between at least one of the input port or the main line and at least one of the coupled port or the coupled line.

In some examples, the at least one capacitive element includes a first capacitor having a first connection coupled to the input port and a second connection coupled to the coupled port. In various examples, the at least one capacitive element includes a second capacitor having a first connection coupled to the output port and a second connection coupled to the isolated port. In at least one example, the coupler includes at least one switching element configured to switchably disconnect at least one of the first capacitor or the second capacitor from at least one of the input port, the output port, the coupled port, or the isolated port. In some examples, the at least one switching element includes a first switch coupled between the first capacitor and the input port and a second switch coupled between the first capacitor and the coupled port.

In various examples, the at least one switching element includes a first switch coupled between the second capacitor and the output port and a second switch coupled between the second capacitor and the isolated port. In at least one example, the coupler includes control circuitry configured to control a switching state of the at least one switching element. In some examples, the coupler is configured to receive an input signal at the input port, the input signal having a signal frequency, and control the switching state of the at least one switching element based on the signal frequency of the input signal. In various examples, the control circuitry is configured to switchably connect the first capacitor and the second capacitor to at least one of the input port, the output port, the coupled port, or the isolated port at a first frequency of the input signal, and is configured to switchably disconnect the first capacitor and the second capacitor from the input port, the output port, the coupled port, and the isolated port at a second frequency of the input signal.

In at least one example, the first frequency is less than the second frequency. In some examples, the first frequency is approximately 1 GHz. In various examples, the second frequency is approximately 3 GHz. In at least one example, the at least one capacitive element includes a capacitor having a first connection coupled directly to the main line and a second connection coupled directly to the coupled line. In some examples, the coupler includes at least one switching element configured to switchably disconnect the capacitor from at least one of the main line or the coupled line. In at least one example, the at least one switching element includes a first switch coupled between the capacitor and the main line and a second switch coupled between the capacitor and the coupled line. In various examples, the coupler includes control circuitry configured to control a switching state of the at least one switching element.

In some examples, the coupler is configured to receive an input signal at the input port, the input signal having a signal frequency, and control the switching state of the at least one switching element based on the signal frequency of the input signal. In various examples, the control circuitry is configured to switchably connect the capacitor to the main line and the coupled line at a first frequency of the input signal, and is configured to switchably disconnect the capacitor from at least one of the main line or the coupled line at a second frequency of the input signal. In at least one example, the first frequency is less than the second frequency. In some examples, the first frequency is approximately 1 GHz. In various examples, the second frequency is approximately 3 GHz.

According to aspects of the disclosure, a coupler comprises an input port, an output port, a coupled port, an isolated port, a main line coupled between the input port and the output port, a coupled line coupled between the coupled port and isolated port, and one or more elements switchably coupled between the coupled port and the isolated port, the one or more elements including at least one of an inductive, capacitive, or resistive element.

In some examples, the one or more elements includes a capacitive element coupled in series between the coupled port and the isolated port. In various examples, the coupler includes at least one switching element coupled in series with the capacitive element and being configured to switchably couple and decouple the capacitive element between the coupled port and the isolated port. In at least one example, the one or more elements further includes an inductive element coupled in parallel with the capacitive element. In some examples, the coupler includes at least one switching element coupled in series with a parallel combination of the capacitive element and the inductive element and being configured to switchably couple and decouple the parallel combination of the capacitive element and the inductive element between the coupled port and the isolated port. In various examples, the capacitive element is a first capacitive element, and the coupler includes a second capacitive element coupled between the coupled port and a reference node, and a third capacitive element coupled between the isolated port and the reference node.

In some examples, the one or more elements further includes at least one inductive element coupled in series with the capacitive element. In at least one example, the coupler includes at least one switching element coupled in series with the at least one inductive element and the capacitive element, and being configured to switchably couple and decouple the at least one inductive element and the capacitive element between the coupled port and the isolated port. In various examples, the one or more elements includes a resistive element coupled in series between the coupled port and the isolated port. In some examples, the coupler includes at least one switching element coupled in series with the resistive element and being configured to switchably couple and decouple the resistive element between the coupled port and the isolated port.

According to aspects of the disclosure, a method of controlling a coupler having an input port, an output port, a coupled port, an isolated port, a main line coupled between the input port and the output port, a coupled line coupled between the coupled port and isolated port, and one or more elements switchably coupled between the coupled port and the isolated port, the one or more elements including at least one of an inductive, capacitive, or resistive element is provided, the method comprising determining a first frequency of a first signal on the main line, coupling the one or more elements between the coupled port and the isolated port based on the first frequency of the first signal, determining a second frequency of a second signal on the main line, and decoupling the one or more elements from the coupled port and the isolated port based on the second frequency of the second signal.

In various examples, the one or more elements includes a capacitive element and the coupler further includes at least one switching element coupled in series with the capacitive element, and the method includes coupling the one or more elements between the coupled port and the isolated port based on the first frequency of the first signal includes controlling the at least one switching element to be in a closed and conducting position, and decoupling the one or more elements from the coupled port and the isolated port based on the second frequency of the second signal includes controlling one or more switching elements of the at least one switching element to be in an open and non-conducting position. In at least one example, the one or more elements further include at least one of a resistive element or an inductive element coupled to the capacitive element.

In some examples, the coupler further includes a first capacitive element coupled between the coupled port and a reference node via a first switching element and a second capacitive element coupled between the isolated port and the reference node via second switching element, and the method includes controlling the first switching element and the second switching element to be in a closed and conducting position to couple the first capacitive element to the coupled port and the second capacitive element to the isolated port, and controlling the first switching element and the second switching element to be in an open and non-conducting position to decouple the first capacitive element from the coupled port and the second capacitive element from the isolated port.

According to at least one example, a non-transitory computer-readable medium is provided storing thereon sequences of computer-executable instructions for controlling a coupler having an input port, an output port, a coupled port, an isolated port, a main line coupled between the input port and the output port, a coupled line coupled between the coupled port and isolated port, and one or more elements switchably coupled between the coupled port and the isolated port, the one or more elements including at least one of an inductive, capacitive, or resistive element, the sequences of computer-executable instructions including instructions that instruct at least one processor to determine a first frequency of a first signal on the main line, couple the one or more elements between the coupled port and the isolated port based on the first frequency of the first signal, determine a second frequency of a second signal on the main line, and decouple the one or more elements from the coupled port and the isolated port based on the second frequency of the second signal.

In some examples, the one or more elements includes a capacitive element and the coupler further includes at least one switching element coupled in series with the capacitive element, and wherein coupling the one or more elements between the coupled port and the isolated port based on the first frequency of the first signal includes controlling the at least one switching element to be in a closed and conducting position, and decoupling the one or more elements from the coupled port and the isolated port based on the second frequency of the second signal includes controlling one or more switching elements of the at least one switching element to be in an open and non-conducting position. In various examples, the one or more elements further includes at least one of a resistive element and an inductive element coupled to the capacitive element.

In at least one example, the coupler further includes a first capacitive element coupled between the coupled port and a reference node via a first switching element and a second capacitive element coupled between the isolated port and the reference node via second switching element, wherein the instructions further instruct the at least one processor to control the first switching element and the second switching element to be in a closed and conducting position to couple the first capacitive element to the coupled port and the second capacitive element to the isolated port, and control the first switching element and the second switching element to be in an open and non-conducting position to decouple the first capacitive element from the coupled port and the second capacitive element from the isolated port.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a radio-frequency (RF) front-end module;

FIG. 2 illustrates a schematic diagram of an RF coupler;

FIG. 3 illustrates a schematic diagram of a coupler according to an example;

FIG. 4 illustrates a graph of a coupling factor as a function of frequency according to an example;

FIG. 5 illustrates a graph of an insertion loss as a function of frequency according to an example;

FIG. 6 illustrates a schematic diagram of a coupler according to an example;

FIG. 7A illustrates a schematic diagram of a coupler according to an example;

FIG. 7B illustrates a graph of a coupling signal at a coupled port and a signal at an isolated port for a coupler according to an example;

FIG. 7C illustrates a graph of a directivity over frequency according to an example;

FIG. 8 illustrates a schematic diagram of a coupler according to an example;

FIG. 9 illustrates a schematic diagram of a coupler according to an example;

FIG. 10A illustrates a schematic diagram of termination impedance elements according to an example;

FIG. 10B illustrates a schematic diagram of termination impedance elements according to an example;

FIG. 11 illustrates a schematic diagram of a coupler according to an example;

FIG. 12 illustrates a graph of an insertion loss as a function of frequency according to an example;

FIG. 13 illustrates a graph of a coupling factor as a function of frequency according to an example;

FIG. 14 illustrates a schematic diagram of a coupler according to an example;

FIG. 15 illustrates a graph of an insertion loss as a function of frequency according to an example;

FIG. 16 illustrates a graph of a coupling factor as a function of frequency according to an example;

FIG. 17 illustrates a schematic diagram of a coupler according to an example;

FIG. 18 illustrates a graph of an insertion loss as a function of frequency according to an example;

FIG. 19 illustrates a graph of a coupling factor as a function of frequency according to an example;

FIG. 20 illustrates a schematic diagram of a coupler according to another example;

FIG. 21 illustrates a graph of an insertion loss as a function of frequency according to an example;

FIG. 22 illustrates a graph of a coupling factor as a function of frequency according to an example;

FIG. 23 illustrates a schematic diagram of a coupler according to another example;

FIG. 24 illustrates a schematic diagram of a coupler according to another example;

FIG. 25 illustrates a graph of an insertion loss as a function of frequency according to an example;

FIG. 26 illustrates a graph of a coupling-factor loss as a function of frequency according to an example;

FIG. 27 illustrates a schematic diagram of a coupler in a first configuration according to another example; and

FIG. 28 illustrates a schematic diagram of the coupler of FIG. 27 in a second configuration according to an example.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

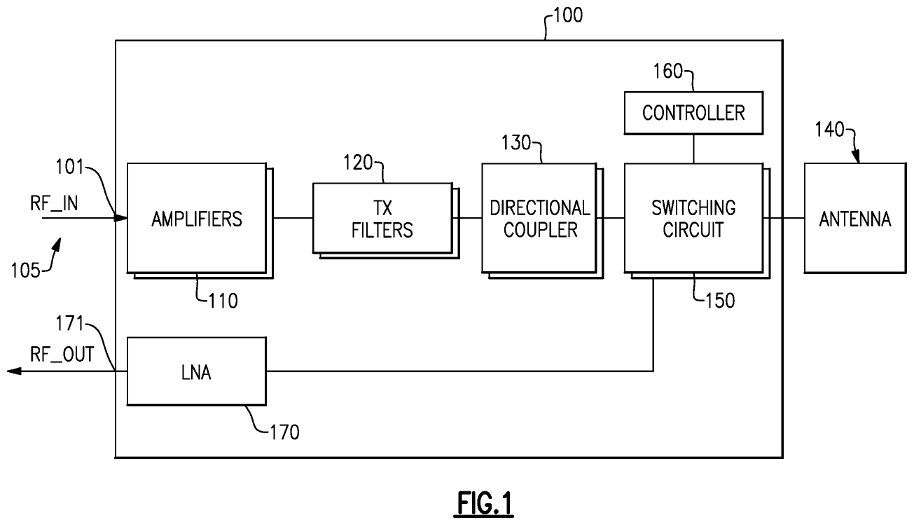

FIG. 1 is a block diagram illustrating an example of a radio-frequency (RF) front-end subsystem or module (FEM) 100 as may be used in a communications device, such as a mobile phone, for example, to transmit and receive RF signals. The FEM 100 shown in FIG. 1 includes a transmit path (TX) configured to provide signals to an antenna for transmission and a receive path (RX) to receive signals from the antenna. In the transmit path (TX), a power-amplifier module 110 provides gain to an RF signal 105 input to the FEM 100 via an input port 101, producing an amplified RF signal. The power-amplifier module 110 can include one or more power amplifiers (PAs).

The FEM 100 can further include a filtering subsystem or module 120, which can include one or more filters. A directional coupler 130 can be used to extract a portion of the power from the RF signal traveling between the power-amplifier module 110 and an antenna 140 connected to the FEM 100. The antenna 140 can transmit the RF signal and can also receive RF signals. A switching circuit 150, also referred to as an antenna switch module (ASM), can be used to switch between a transmitting mode and receiving mode of the FEM 100, for example, or between different transmit or receive frequency bands. In certain examples, the switching circuit 150 can be operated under the control of a controller 160. As shown, the directional coupler 130 can be positioned between the filtering subsystem 120 and the switching circuit 150. In other examples, the directional coupler 130 may be positioned between the power-amplifier module 110 and the filtering subsystem 120, or between the switching circuit 150 and the antenna 140.

The FEM 100 can also include a receive path (RX) configured to process signals received by the antenna 140 and provide the received signals to a signal processor (for example, a transceiver) via an output port 171. The receive path (RX) can include one or more low-noise amplifiers (LNAs) 170 to amplify the signals received from the antenna. Although not shown, the receive path (RX) can also include one or more filters for filtering the received signals.

As described above, directional couplers (for example, directional coupler 130) can be used in FEM products, such as radio transceivers, wireless handsets, and the like. For example, directional couplers can be used to detect and monitor RF output power. When an RF signal generated by an RF source is provided to a load, such as to an antenna, a portion of the RF signal can be reflected from the load back toward the RF source. An RF coupler can be included in a signal path between the RF source and the load to provide an indication of forward RF power of the RF signal traveling from the RF source to the load and/or an indication of reverse RF power reflected from the load. RF couplers include, for example, directional couplers, bidirectional couplers, multi-band couplers (for example, dual band couplers), and the like.

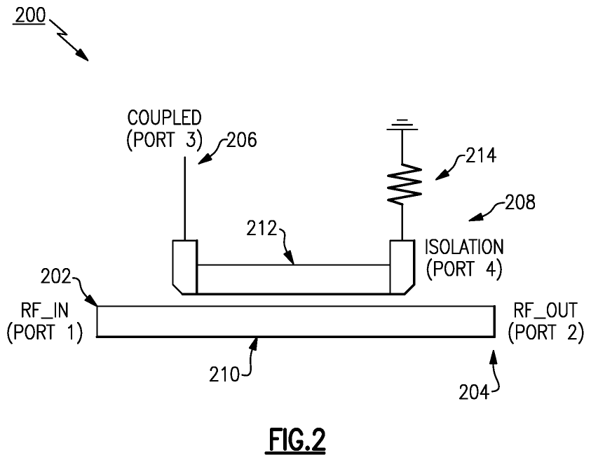

Referring to FIG. 2, an RF coupler 200 includes a power input port 202, a power output port 204, a coupled port 206, and an isolation port 208. An electromagnetic coupling mechanism, which can include inductive or capacitive coupling (or both), may be provided by two parallel or overlapped transmission lines, such as microstrips, strip lines, coplanar lines, and the like. The transmission line 210 extending between the power input port 202 and the power output port 204 is termed the main line and can provide the majority of the signal from the power input port 202 to the power output port 204. The transmission line 212 extending between the coupled port 206 and the isolation port 208 is termed the coupled line and can be used to extract a portion of the power traveling between the power input port 202 and the power output port 204 for measurement. In some examples, the amount of inductance provided by each of the transmission lines 210, 212 corresponds to the length of each transmission line. In certain examples, inductor coils may be used in place of the transmission lines 210, 212.

When a termination impedance 214 is presented to the isolation port 208 (as shown in FIG. 2), an indication of forward RF power traveling from the power input port 202 to the power output port 204 is provided at the coupled port 206. Similarly, when a termination impedance is presented to the coupled port 206, an indication of reverse RF power traveling from the power output port 204 to the power input port 202 is provided at the coupled port 206, which is now effectively the isolation port for reverse RF power. The termination impedance 214 may be implemented by a 50 Ohm shunt resistor in a variety of existing RF couplers. However, in other examples, the termination impedance 214 may provide a different impedance value for a specific frequency of operation, or for a specific amount of capacitive coupling between the lines 210, 212. In some examples, the termination impedance 214 may be adjustable to support multiple frequencies of operation and/or various amounts of capacitive coupling between the lines 210, 212. As discussed in greater detail below, a desirable amount of capacitive coupling may vary based on a frequency of operation. Accordingly, a particular frequency of operation may correspond to a particular amount of capacitive coupling.

In one example, the RF coupler 200 is configured to provide a coupling factor corresponding to the mutual coupling of the transmission line 210 (or first inductor coil) to the transmission line 212 (or second inductor coil) and the capacitive coupling of the transmission line 210 (or first inductor coil) to the transmission line 212 (or second inductor coil). In some examples, the coupling factor may be a function of the spacing between the transmission lines 210, 212 and the inductance of the transmission lines 210, 212. In many cases, the coupling factor increases as frequency increases. As the coupling factor increases, more power is coupled from the main line (that is, transmission line 210) to the coupled line (that is, transmission line 212), increasing the insertion loss of the RF coupler 200.

RF couplers are typically designed to achieve a desired coupling factor at a specific frequency (or band). However, in some cases, RF couplers may be bidirectional and configured for use in multi-mode, multi-frequency applications. For example, an RF coupler may be included in a FEM (for example, the FEM 100 of FIG. 1) configured to operate in a first mode of operation and a second mode of operation. In one example, the first mode of operation may correspond to low-frequency signals (for example, 1 GHz) and the second mode of operation may correspond to high-frequency signals (for example, 3 GHz). In some examples, the RF coupler may be designed to achieve a desired coupling factor during the first mode of operation and the coupling factor may be stronger than intended or desired during the second mode of operation. As such, an attenuator may be used to reduce the coupled power during the second mode of operation. Likewise, the insertion loss of the RF coupler may increase during the second mode of operation and the output power of the power-amplifier module 110 (or another RF source) may be increased during the second mode of operation to compensate for the increased insertion loss.

In some examples, the inclusion of an attenuator to reduce the coupled power during the second mode of operation (that is, high-frequency mode) can increase the footprint of the RF coupler and the overall package size of the FEM. In addition, by attenuating the coupled power during the second mode of operation, the accuracy of the output power monitoring provided by the RF coupler may be reduced. For example, the attenuation provided by the attenuator may not compensate the exact amount of excess power corresponding to the increased coupling factor and the exact value of attenuation provided the attenuator may vary. Likewise, a bypass switch may be needed to bypass the attenuator during the first mode of operation (that is, low-frequency mode). Besides occupying extra space, the bypass switch may provide additional loss in the coupled power signal path. In addition, operating the power-amplifier module 110 (or another RF source) to provide higher output power during the second mode of operation may reduce the efficiency of the power-amplifier module 110 and increase the power consumption of the FEM 100.

Alternatively, to support the first and second modes of operation, the FEM 100 can be configured to include separate RF couplers for each mode. For example, the FEM 100 may include a first RF coupler designed to achieve a desired coupling factor during the first mode of operation and a second RF coupler designed to achieve a desired coupling factor during the second mode of operation. However, the inclusion of separate RF couplers may increase the footprint and/or package size of the FEM 100. In addition, the switching circuitry needed to switch between the RF couplers may also increase footprint and/or package size of the FEM 100 any may introduce additional loss in the signal paths.

In light of the foregoing, in various examples, a coupler includes at least one switchable element switchably coupled between a main line and a coupled line. The switchable element may include a switchable capacitor configured to provide variable capacitive coupling between the main line and the coupled line. As discussed above, a coupling factor may depend on a degree of capacitive coupling between the main line and the coupled line. Consequently, a coupling factor between the main line and the coupled line may be controlled by engaging a switchable capacitive coupling between the main line and coupled line. For example, where a coupler operates in a first mode of operation in which low-frequency (for example, 1 GHz) signals are output by the coupler, the coupling factor may be increased by switchably connecting at least one capacitive element between the main and coupled lines. In a second mode of operation in which high-frequency (for example, 3-5 GHz) signals are output by the coupler, the coupling factor may be decreased by disconnecting the at least one capacitive element from between the main and coupled lines. Accordingly, a coupler having at least one switchable element, such as a capacitor, coupling a main line to a coupled line is provided such that a coupling factor may be modified based on an operating state of the coupler.

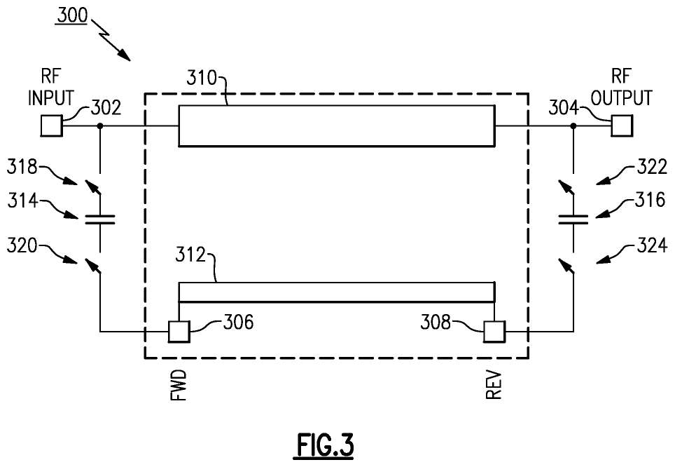

FIG. 3 illustrates a schematic diagram of a coupler 300 according to an example. The coupler 300 includes an input port 302, an output port 304, a coupled port 306, an isolated port 308, a main line 310, a coupled line 312, a first capacitive element 314, a second capacitive element 316, a first switching element 318, a second switching element 320, a third switching element 322, and a fourth switching element 324. The input port 302 may be substantially similar to the power input port 202. The output port 304 may be substantially similar to the power output port 204. The coupled port 306 may be substantially similar to the coupled port 206. The isolated port 308 may be substantially similar to the isolated port 208. The main line 310 may be substantially similar to the transmission line 210. The coupled line 312 may be substantially similar to the transmission line 212.

The first capacitive element 314 is coupled between the first switching element 318 and the second switching element 320. The second capacitive element 316 is coupled between the third switching element 322 and the fourth switching element 324. The first switching element 318 includes a first connection coupled to the input port 302, and a second connection coupled to the first capacitive element 314. The second switching element 320 includes a first connection coupled to the first capacitive element 314 and a second connection coupled to the coupled port 306. The third switching element 322 includes a first connection coupled to the output port 304, and a second connection coupled to the second capacitive element 316. The fourth switching element 324 includes a first connection coupled to the second capacitive element 316, and a second connection coupled to the isolated port 308.

Each of the switching elements 318-324 may be switchable independently from one another in some examples, and may be switchable dependent on one another in other examples. For example, the switches 318, 320 may be switched together as a pair, and the switches 322, 324 may be switched together as a pair, in some examples. In other examples, one or more of the switches 318-324 may be switched independently.

The first switching element 318 may switchably couple the input port 302 to the first capacitive element 314. The second switching element 320 may switchably couple the first capacitive element 314 to the coupled port 306. The third switching element 322 may switchably couple the output port 304 to the second capacitive element 316. The fourth switching element 324 may switchably couple the second capacitive element 316 to the isolated port 308.

The switching elements 318-324 may be switchably controlled to control a capacitive coupling between the main line 310 and the coupled line 312. A switching state of each of the switching elements 318-324 may be controlled by providing signals (for example, bias-control signals) to respective control terminals of the switching elements 318-324. In various examples, the coupler 300 may include, or be coupled to, control circuitry to provide control signals to a respective control terminal of each of the switching elements 318-324. For example, the switching elements 318-324 may include metal-oxide field-effect transistors (MOSFETs) each having a gate connection to receive one or more control signals from the control circuitry.

A capacitive coupling between the lines 310, 312 may increase as bias-control signals are provided to the switches 318-324 to enable the switches 318-324 to enter a closed and conducting state. Accordingly, an amount of capacitive coupling (and, consequently, a coupling factor) between the lines 310, 312 may be controlled by controlling a state of the switching elements 318-324. In various examples, the amount of capacitive coupling between the lines 310, 312 may be increased as a frequency of a signal provided at the output port 304 decreases, such that a coupling factor may be selectively increased at lower frequencies without necessarily increasing a coupling factor at higher frequencies.

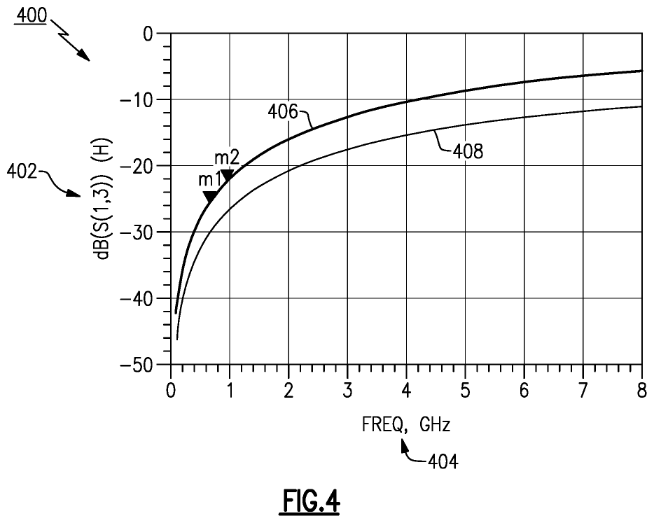

FIG. 4 illustrates a graph 400 of a coupling factor as a function of frequency according to an example. The y-axis 402 indicates a coupling factor measured in decibels (dB). For example, the y-axis 402 may indicate a coupling factor between the lines 310, 312. The x-axis 404 indicates a frequency measured in gigahertz (GHz). For example, the x-axis 404 may indicate a frequency of a signal conducted in the main line 310. The graph 400 includes a first trace 406 and a second trace 408. The first trace 406 may indicate a coupling factor where the first capacitive element 314 and the second capacitive element 316 switchably connect the lines 310, 312, although in some examples, only one of the elements 314, 316 may switchably connect the lines 310, 312. The second trace 408 may indicate a coupling factor where the first capacitive element 314 and the second capacitive element 316 do not switchably connect the lines 310, 312, although in some examples, only one of the elements 314, 316 may be switchably disconnected between the lines 310, 312.

As indicated by the traces 406, 408, the coupling factor increases as frequency increases. The value of the first trace 406 may be greater than or substantially equal to the second trace 408 at all frequencies, indicating that an input signal is more strongly coupled to the coupled port 306 where at least one of the capacitive elements 314, 316 connects the lines 310, 312, as compared to the capacitive elements 314, 316 not connecting the lines 310, 312, such as where the switching elements 318-324 are open and non-conductive. The traces 406, 408 may increasingly diverge as the frequency increases.

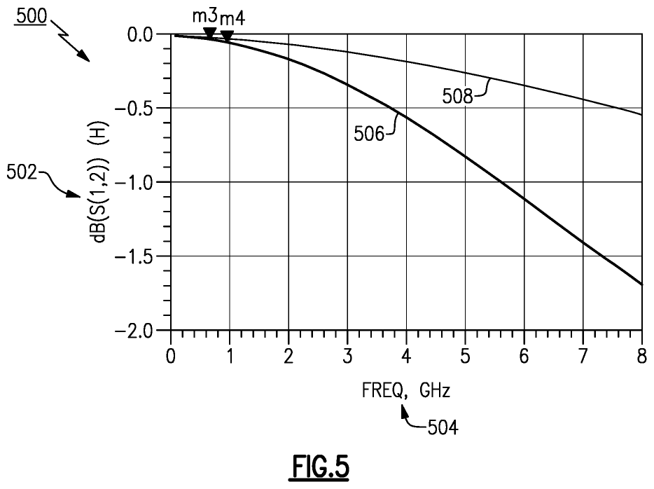

FIG. 5 illustrates a graph 500 of an insertion loss as a function of frequency according to an example. The y-axis 502 indicates an insertion loss measured in dB. For example, the y-axis 502 may indicate an insertion loss of a signal provided at the input port 302. The x-axis 504 indicates a frequency measured in GHz. For example, the x-axis 504 may indicate a frequency of a signal conducted in the main line 310. The graph 500 includes a first trace 506 and a second trace 508. The first trace 506 may indicate an insertion loss where the first capacitive element 314 and the second capacitive element 316 switchably connect the lines 310, 312, although in some examples, only one of the elements 314, 316 may switchably connect the lines 310, 312. The second trace 508 may indicate an insertion loss where the first capacitive element 314 and/or the second capacitive element 316 do not switchably connect the lines 310, 312, although in some examples, only one of the elements 314, 316 may switchably be switchably disconnected between the lines 310, 312.

As indicated by the traces 506, 508, the insertion loss decreases as frequency increases. A value of the first trace 506 may be less than or substantially equal to the second trace 508 at all frequencies, indicating that a greater proportion of an input signal is lost to the coupled port 306 where at least one of the capacitive elements 314, 316 connects the lines 310, 312, as compared to the capacitive elements 314, 316 not connecting the lines 310, 312, such as where the switching elements 318-324 are open and non-conductive. The traces 506, 508 may increasingly diverge as the frequency increases.

As discussed above, it may be advantageous to increase a capacitive coupling between the lines 310, 312 at lower frequencies (for example, approximately 1 GHz) without increasing a capacitive coupling between the lines 310, 312 at higher frequencies (for example, approximately 3 GHz). In various examples, the capacitive elements 314, 316 may be switchably disconnected from the lines 310, 312 at higher frequencies when less capacitive coupling is desirable, and may be switchably connected to the lines 310, 312 at lower frequencies when more capacitive coupling is desirable.

At a frequency of 1 GHz, for example, an insertion loss may differ negligibly where the capacitive elements 314, 316 are switchably coupled and decoupled between the lines 310, 312, as indicated by the traces 506, 508, whereas at a frequency of 3 GHz, an insertion loss may differ appreciably where the capacitive elements 314, 316 are switchably coupled and decoupled between the lines 310, 312, as indicated by the traces 506, 508. Accordingly, a capacitive coupling between the lines 310, 312 may be increased by switchably coupling the capacitive elements 314, 316 to the lines 310, 312 at lower frequencies at which an insertion loss is not significantly affected, but may not be increased by switchably decoupling the capacitive elements 314, 316 from the lines 310, 312 at higher frequencies at which an insertion loss is appreciably affected.

In some examples, the coupler 300 may operate in one or more discrete modes of operation corresponding to respective frequencies, such as discrete frequency bands. For example, the coupler 300 may operate in a first mode of operation in which a signal provided at the output port 304 has a frequency of approximately 1 GHz, a second mode of operation in which a signal provided at the output port 304 has a frequency of approximately 3 GHz, and one or more additional modes of operation in which a signal provided at the output port 304 has other frequencies. In various examples, the coupler 300 may switchably connect the capacitive elements 314, 316 between the lines 310, 312 based on a modes of operation in which the coupler 300 is operating, and disconnect the capacitive elements 314, 316 from the lines 310, 312 at other modes of operation corresponding to other frequencies. As discussed in greater detail below, the coupler 300 may include or be coupled to control circuitry configured to select an appropriate mode of operation (for example, based on a frequency band at which the coupler 300 is operating) and control components of the coupler 300 in accordance with the selected mode of operation.

In other examples, the coupler 300 may operate across a continuous range of frequencies. In various examples, the coupler 300 may switchably connect the capacitive elements 314, 316 between the lines 310, 312 within certain ranges of frequencies, and disconnect the capacitive elements 314, 316 from the lines 310, 312 at other ranges of frequencies. In some examples, bias-control signals may be provided (for example, by control circuitry) to the switching elements 318-324 to vary a duty cycle of the switching elements 318-324. A duty cycle of the switching elements 318-324 may decrease as a frequency of a signal output at the output port 304 increases, such that a capacitive coupling between the lines 310, 312 decreases as the frequency of the signal output at the output port 304 increases. Accordingly, a capacitive coupling between the lines 310, 312 may be modulated according to a frequency of a signal output at the output port 304 by varying a connection of the capacitive elements 314, 316 between the lines 310, 312 according to a variety of implementations.

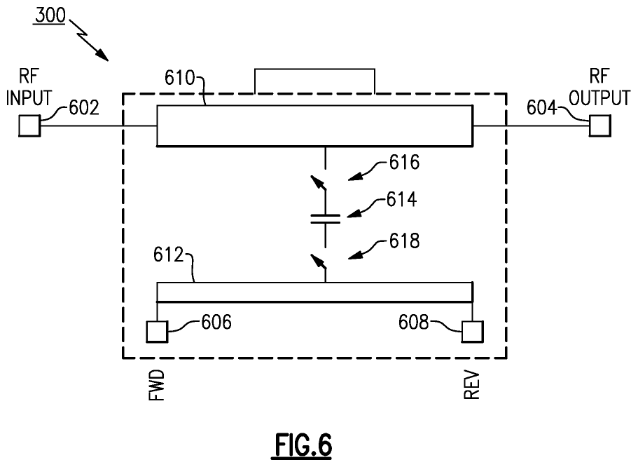

Although the capacitive elements 314, 316 are switchably coupled between the ports 302, 306 and 304, 308 in some examples, in other examples, switchable capacitive coupling between the lines 310, 312 may be achieved through alternate implementations. FIG. 6 illustrates a schematic diagram of a coupler 600 according to another example. The coupler 600 includes an input port 602, an output port 604, a coupled port 606, an isolation port 608, a main line 610, and a coupled line 612, which may be substantially similar to the components 302-312.

The coupler 600 further includes a capacitive element 614, a first switching element 616, and a second switching element 618. The capacitive element 614 is coupled between the switching elements 616, 618. The first switching element 616 is coupled between the main line 610 and the capacitive element 614. The second switching element 618 is coupled between the capacitive element 614 and the coupled line 612. The coupler 600 may operate in a substantially similar manner as the coupler 300 to provide variable capacitive coupling between the main line 310 and the coupled line 312, albeit with the components 614-618 operating in lieu of the components 314-324. Accordingly, various implementations of variable capacitive coupling between a main line and a coupled line are within the scope of the disclosure.

Varying an amount of capacitive coupling between a main line and a coupled line may affect other parameters of a coupler, such as directivity. Directivity of an RF coupler can be dependent on the termination impedance at the isolated port. In some examples, a termination impedance may have a fixed impedance. However, with a fixed termination impedance, the coupler may not have a desired directivity when an RF signal is outside of a particular frequency band and/or amount of capacitive coupling between main and coupled lines for which the termination impedance may be optimized. Thus, when operating in a different frequency band outside of the particular frequency band and/or with a different amount of capacitive coupling between the main and coupled lines, directivity may not be optimized.

Adjusting the termination impedance electrically connected to a port of an RF coupler can improve directivity of the RF coupler by providing a desired termination impedance for certain operating conditions. For example, operating conditions may include an amount of capacitive coupling between a main line and a coupled line, such as the lines 310, 312 and/or the lines 610, 612. As discussed above, an amount of capacitive coupling between the main line and the coupled line may be controlled based on a frequency at which the coupler is operating. Accordingly, a termination impedance may be selectively controlled based at least in part on an amount of capacitive coupling and/or a frequency band at which the coupler is operating.

In certain examples, a switch network can selectively electrically couple different termination impedances to the isolated port of a coupler, such as the coupler 300 and/or 600, responsive to one or more control signals. The switch network can adjust the termination impedance of the radio frequency coupler to improve directivity across various operating conditions. The switch network can include switches between termination impedances at both the isolated port and the coupled port. Such an RF coupler can have a termination impedance provided to the isolated port for providing an indication of forward RF power in one state and have a termination impedance provided to the coupled port for providing an indication of reverse RF power in another state.

In certain examples, a termination impedance circuit including a plurality of switches can adjust the termination impedance provided to an isolated port and/or a coupled port of an RF coupler by selectively providing resistance, capacitance, inductance, or any combination thereof in a termination path. The termination impedance circuit can provide any suitable termination impedance by selectively electrically coupling passive impedance elements in series and/or in parallel in the termination path. The termination impedance circuit can thereby provide a termination impedance having a desired impedance value. The termination impedance circuit can compensate for variations in a capacitive coupling between main and coupled lines, for example. In some examples, data indicative of a desired termination impedance can be stored in memory and a state of at least one of the switches of the plurality of switches can be set based at least partly on the data stored in the memory. In some implementations, the memory can include persistent memory, such as fuse elements (for example, fuses and/or antifuses), to store the data.

According to various examples, a switch can be disposed between a port of an RF coupler (for example, a coupled port or an isolated port) and an adjustable termination impedance circuit. The switch can electrically isolate tuning elements (for example, switches) of the adjustable termination impedance circuit from the port of the RF coupler when the adjustable termination impedance circuit is not providing a termination impedance to the port of the RF coupler. This can reduce loading effects, such as of capacitances of switches in the adjustable termination impedance circuit, on the port of the RF coupler. Accordingly, the switch can enable an insertion loss on the port of the RF coupler to be decreased.

In accordance with some examples, a termination impedance circuit can be shared by an isolated port and a coupled port of a bi-directional coupler. This can reduce the area relative to having separate termination impedance circuits for the isolated port and the coupled port. Only one of the isolated port or the coupled port can be provided with a termination impedance at a time to provide an indication of RF power. Accordingly, a switch circuit can selectively electrically connect the termination impedance circuit to the isolated port and selectively electrically connect the termination impedance circuit to the coupled port such that no more than one of the isolated port or the coupled port is electrically connected to the termination impedance circuit at a time. To electrically isolate the coupled port and the isolated port, the switch circuit can include high-isolation switches. Each of the high-isolation switches can include a series-shunt-series circuity topology, for example. The isolation between the coupled port and the isolated port provided by the high-isolation switches can be greater than a target directivity.

The RF couplers discussed herein can have a decoupled state in which the coupled line is decoupled from a main line. The decoupled state can provide a minimal insertion loss in a main signal line when the RF coupler is unused.

Examples discussed herein can advantageously provide an improved directivity for an RF coupler by providing a termination impedance that is selected for particular operating conditions, such as a particular frequency band of an RF signal provided to the RF coupler and/or a particular amount of capacitive coupling between the main and coupled lines. In certain examples, the RF couplers discussed herein have a decoupled state that can minimize loss due to coupling effects when the RF coupler is unused.

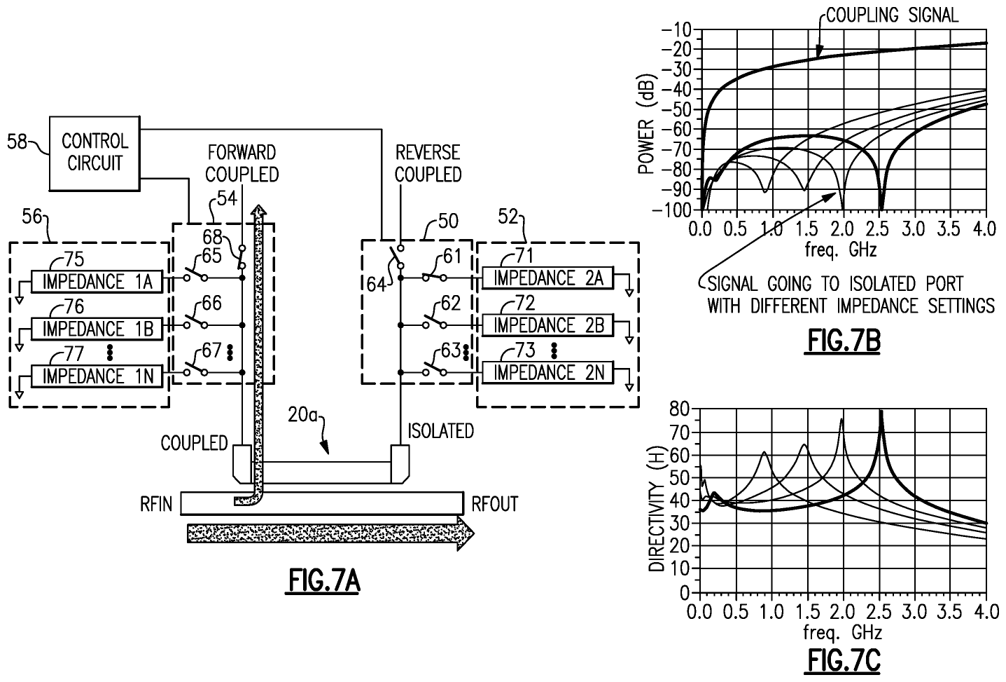

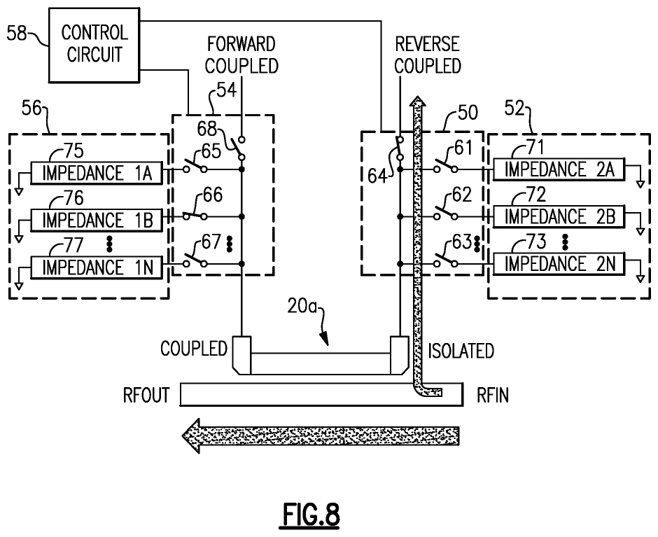

Referring to FIG. 7A, an electronic system that includes an RF coupler 20a and an adjustable termination-impedance circuit according to an example are provided. The RF coupler 20a may be an example of a coupler described above, such as the couplers 300, 600, except that capacitive coupling elements switchably coupling the main and coupled lines are omitted for purposes of explanation. When the electronic system is in the state illustrated in FIG. 7A, a portion of RF power traveling from the power input port to the power output port is being provided to the coupled port. The portion of RF power provided to the coupled port of the RF coupler 20a in FIG. 7A is representative of forward RF power. An indication of the forward RF power at the coupled port of the RF coupler 20a can be indicative of power of a signal generated by a power amplifier provided to an antenna, for example. FIG. 7A illustrates an electronic system that includes an RF coupler 20a, a first switch network 50, first termination impedance elements 52, a second switch network 54, second termination impedance elements 56, and a control circuit 58. The electronic system of FIG. 7A can include more elements than illustrated and/or a sub-combination of the illustrated elements can be implemented.

The RF coupler 20a can include two parallel or overlapped transmission lines, such as microstrips, strip lines, coplanar lines, and so forth. In some examples, the RF coupler 20a can include two inductors, such as two transformers, in place of the two transmission lines. The two transmission lines or inductors can implement a main line and a coupled line. The main line can provide the majority of the signal from the RF power input to the RF power output. The coupled line can be used to extract a portion of the power traveling between the RF power input and the RF power output.

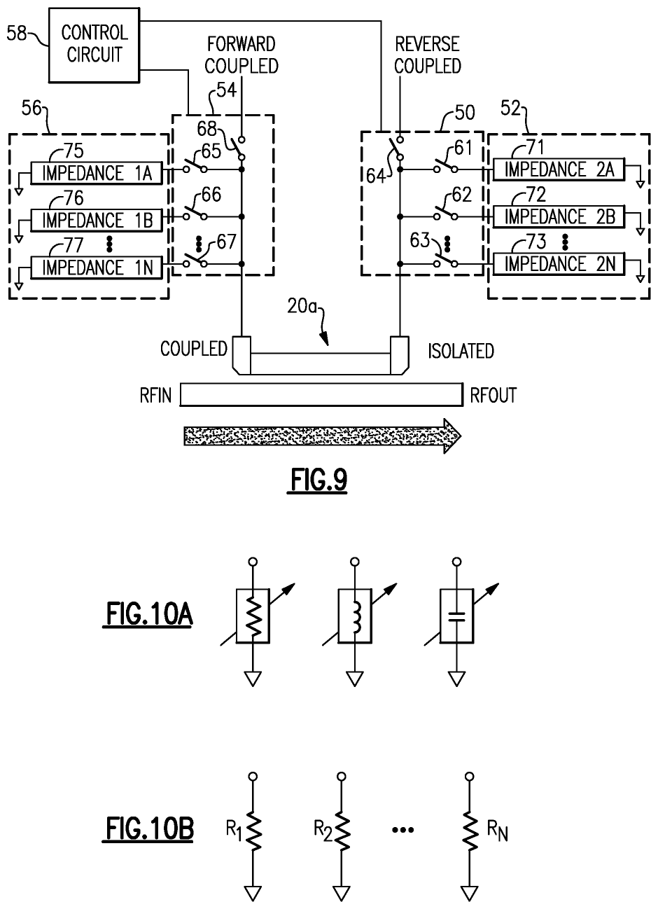

In FIG. 7A, the first switch network 50 and the first termination impedance elements 52 can together implement a first adjustable termination impedance circuit. The first adjustable termination impedance circuit can provide a selected termination impedance to the isolated port of the RF coupler 20a. The second switch network 54 and the second termination impedance elements 56 can together implement a second adjustable termination impedance circuit. The second adjustable termination impedance circuit can provide a selected termination impedance to the coupled port of the RF coupler 20a as will be discussed in more detail with reference to FIG. 8. While each of the first adjustable termination impedance circuit and the second adjustable termination impedance circuit of FIG. 7A includes switches and termination impedances electrically connected to respective switches, the first adjustable termination impedance circuit and/or the second adjustable termination impedance circuit can be implemented by any suitable adjustable termination impedance circuit.

The isolated port of the RF coupler 20a can be electrically connected to one or more switches to adjust the termination impedance provided to the isolated port. As illustrated, the first switch network 50 includes impedance-select switches 61, 62, and 63 to selectively electrically couple termination impedances 71, 72, and 73, respectively, of the first termination impedance elements 52 to the isolated port of the RF coupler 20a. The illustrated first switch network 50 also includes a mode-select switch 64 which can selectively provide a reverse-coupled output from the RF coupler 20a when the RF coupler 20a is being used to provide an indication of reverse RF power.

Each of the switches of the first switch network 50 can electrically couple nodes when on and electrically isolate nodes when off. The first switch network 50 can include any suitable switches to implement the impedance-select switches 61, 62, and 63 and the mode-select switch 64. For example, each of the illustrated switches in the first switching network 50 can include a semiconductor field-effect transistor (FET). Such a FET can be biased in the linear mode, for example. When the FET is on, the FET can be in a short circuit or low-loss mode that electrically connects a source and a drain of the FET. When the FET is off, the FET can be in an open circuit or high-loss mode that electrically isolates the source and the drain of the FET. Other suitable switches can alternatively or additionally be implemented. Moreover, while three impedance-select switches 61, 62, and 63 are illustrated in FIG. 7A, any suitable number of impedance-select switches can be implemented. In some instances, only one impedance-select switch may be implemented. In some other instances, two impedance-select switches can be implemented or more than three impedance-select switches can be implemented.

The impedance-select switches 61, 62, and 63 and the termination impedances 71, 72, and 73 can be used to achieve a desired directivity of the RF coupler 20a. For example, different termination impedances can be selectively electrically coupled to the isolated port as an amount of capacitive coupling between the main and coupled lines of a coupler is varied. As an illustrative example, a first termination impedance 71 can be electrically coupled to the isolated port for a first amount of capacitive coupling, a second termination impedance 72 can be electrically coupled to the isolated port for a second amount of capacitive coupling, and a third termination impedance 73 can be electrically coupled to the isolated port for a third amount of capacitive coupling.

The impedance-select switches 61, 62, and 63 can be controlled so as to provide any suitable combination of termination impedances 71, 72, and/or 73 to the isolated port of the RF coupler 20a. Moreover, the principles and advantages discussed herein can be applied to any suitable number of impedance-select switches and corresponding termination impedances. Alternatively or additionally, a particular termination impedance or combination of termination impedances can be selected for a particular power mode of operation. Having a particular impedance for a particular power mode and/or amount of capacitive coupling can improve the directivity of the RF coupler 20a, which can aid in improving, for example, the accuracy of power measurements associated with the RF coupler 20a. A particular termination impedance or combination of termination impedances can be selected for any suitable application parameter(s) and/or any suitable indication of operating condition(s).

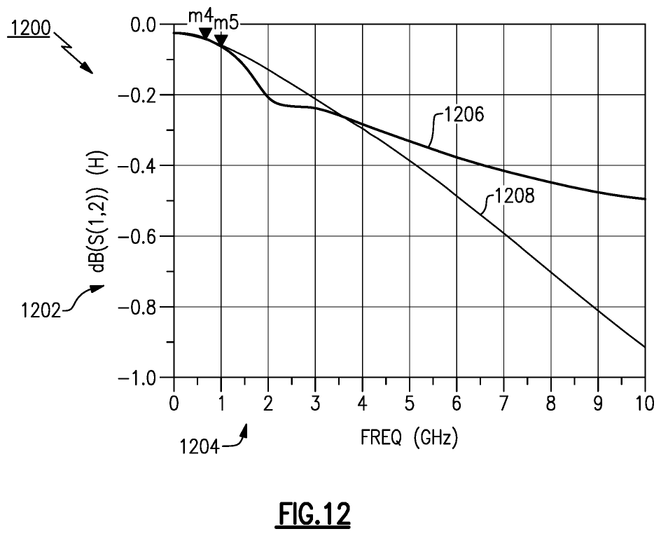

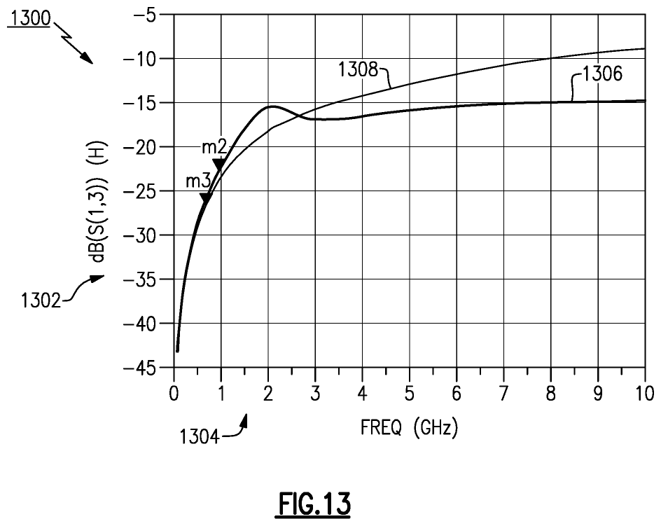

The first termination-impedance elements 52 of FIG. 7A include a termination impedance electrically connected to each impedance-select switch of the first switching network. The termination impedances 71, 72, and 73 can be, for example, resistive, capacitive, and/or inductive loads selected to achieve a desired termination impedance. Such a desired termination impedance can be selected for a particular amount of capacitive coupling and/or power mode. One or more of the termination impedances can be a passive impedance element electrically coupled between a mode-select switch and a ground potential. For example, a termination impedance can be implemented by a resistor electrically coupled between an impedance-select switch and ground. One or more termination impedances can include any suitable combination of series and/or parallel passive impedance elements. For instance, a termination impedance can be implemented by a capacitor and a resistor in series between an impedance-select switch and a ground potential. More detail regarding example termination impedance elements will be provided in connection with FIGS. 10A and 10B.

The control circuit 58 can control the impedance-select switches 61, 62, and 63 such that a desired terminating impedance is provided to the isolated port of the RF coupler 20a when the electronic system is in a state to provide an indication of forward RF power. The control circuity 58 can include any suitable circuitry for selectively opening and closing one or more of the impedance-select switches 61, 62, 63 to achieve the desired termination impedance at the isolated terminal. For example, the control circuit 58 can configure the impedance-select switches 61, 62, and 63 into any combination of switching states. In some examples, the control circuit 58 may further control components of the couplers 300, 600, such as one or more of the switching elements 318-324, 616, 618, by sending control signals (for example, bias-control signals) to respective switching elements.

The control circuit 58 can receive a first signal indicative of whether to measure forward power or reverse power and a second signal indicative of a mode of operation, such as a band-select and/or capacitance-select signal indicating a desired amount of capacitive coupling. From the received signals, the control circuit 58 can control the first switch network 50 to provide a selected termination impedance to isolated port of the RF coupler 20a. The selected termination impedance can be implemented by any suitable combination of the termination impedances 71, 72, 73. From the received signals, the control circuit 58 can control the second switch network 54 to provide a selected termination impedance to the coupled port of the RF coupler 20a for measuring reverse power. The control circuit 58 can control the mode-select switches 64 and 68 based on the state of the first signal.

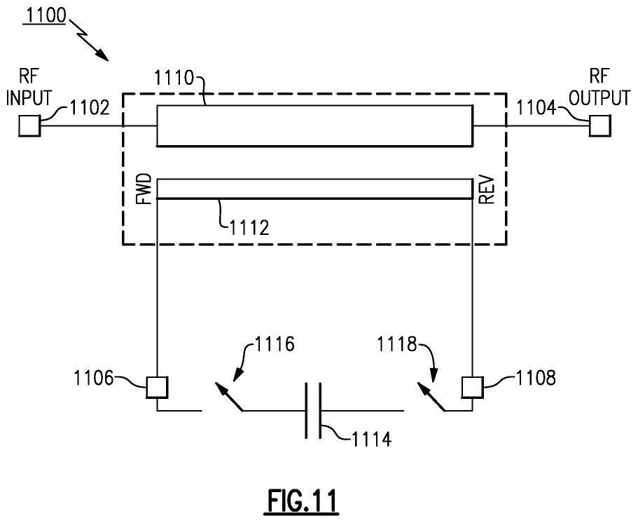

In some states, such as the states illustrated in FIGS. 8 and 9, the control circuit 58 can decouple the isolated port from all termination impedances of the first termination impedance elements 52.

When the electronic system is in the state illustrated in FIG. 7A, the control circuit 58 controls the switch network 50 to electrically connect the first terminating impedance 71 to the isolated port of the RF coupler 20a by way of the first impedance-select switch 61 while electrically isolating the other terminating impedances from the isolated port using the other impedance-select switches 62 and 63. The control circuit 58 can include digital logic, such as a decoder, for operating the impedance select switches 61, 62, 63. The digital logic can operate on any suitable power supply, including, for example, an output voltage of a charge pump or a battery voltage. The control circuit 58 can also control the mode select switch 64 of the first switch network 50 such that the isolated port is decoupled from a reflected power output in the state illustrated in FIG. 7A. When operating in the state illustrated in FIG. 7A, the control circuit 58 provides input signals to the second switch network 54 such that the mode select switch 68 electrically connects the coupled port to a forward power output and the impedance select switches 65, 66, and 67 electrically isolate the coupled port from the terminating impedances 75, 76, and 77, respectively.

FIG. 7B is a graph illustrating a coupling signal at a coupled port and a signal at an isolated port for the RF coupler 20a arranged as illustrated in FIG. 7A. FIG. 7B shows that different termination impedances provided to the isolated port of the RF coupler 20a can optimize a minimum amount of signal at the isolated port at corresponding different frequencies. In various examples, different frequencies may correspond to (for example, may influence the selection of) respective amounts of capacitive coupling. Accordingly, FIG. 7B may indirectly illustrate that different termination impedances can be optimally selected based on a selected amount of capacitive coupling.

FIG. 7C is a graph illustrating a relationship of directivity over frequency corresponding to the curves shown in FIG. 7B. Directivity can represent a measure of a power of the coupling signal minus a measure of a power of the signal at the isolated port. Higher directivities can be more desirable. As shown in FIG. 7C, directivity can be optimized at selected frequencies by providing particular termination impedances to the isolated port of the RF coupler 20a. Accordingly, directivity can be optimized at selected amounts of capacitive coupling, which may correspond to a respective frequency.

FIG. 8 is a schematic diagram illustrating the electronic system of FIG. 7A configured in a different state than in FIG. 7A in which a portion of power of an RF signal traveling in an opposite direction is extracted. Instead of providing an indication of forward power at a forward coupled output as shown in FIG. 7A, the electronic system can provide an indication of reverse power at a reverse-coupled output as shown in FIG. 8. Accordingly, the RF coupler 20a can be used to detect reverse power, such as power reflected back from an antenna coupled to the RF coupler 20a. To provide an indication of reverse power, a termination impedance can be provided to the coupled port of the RF coupler 20a. Having switch networks coupled to the coupled port and the isolated port of the RF coupler 20a can enable the RF coupler 20a to be bi-directional.

The second switch network 54 can electrically couple a selected termination impedance of the second termination impedance elements 56 to the coupled port of the RF coupler 20a. The second switch network 54 can also selectively couple and/or decouple the coupled port to and/or from the forward-coupled output. Any combination of features of the first switch network 50 described with reference to the isolated port of the RF coupler 20a can be implemented by the second switch network 54 in connection with the coupled port of the RF coupler 20a.

The impedance-select switches 65, 66, and 67 can be controlled to be in a selected state corresponding to a respective operating mode. In the state shown in FIG. 8, the impedance-select switch 66 electrically connects the termination impedance 76 to the coupled port of the RF coupler 20a and the other impedance-select switches 65 and 67 of the second switch network 54 electrically isolate respective termination impedances 75 and 77 from the coupled port of the RF coupler 20a.

The impedance-select switches 65, 66, and 67 can be controlled so as to provide any suitable combination of termination impedances 75, 76, and/or 77 to the coupled port of the RF coupler 20a. For example, the impedance-select switches 65, 66, and 67 can be configured into any combination or sub-combination of switching states. Moreover, the principles and advantages discussed herein can be applied to any suitable number of impedance-select switches and corresponding termination impedances.

Any combination of features of the first termination impedance elements 52 described in connection with the isolated port can be implemented by the second termination impedance elements 56 in connection to the coupled port. In some examples, the second termination impedance elements 56 include different termination impedances than the first termination impedance elements 52. According to some other examples, the second termination impedance elements 56 include substantially the same termination impedances as the first termination impedance elements 52. In certain examples, one or more termination impedances can be electrically couplable to the isolated port and also electrically couplable to the coupled port.

As illustrated in FIG. 8, an impedance-select switch 66 electrically connects a termination impedance 76 to the coupled port of the RF coupler 20a. This can set a desired directivity for providing an indication of reverse power for a particular amount of capacitive coupling. As also illustrated in FIG. 8, a mode-select switch 68 of the second switch network 54 can electrically isolate the coupled port from the forward-coupled output and the mode-select switch 64 of the first switch network 50 can electrically connect the isolated port to the reverse-coupled output. The control circuit 58 can change states of the switches in the first switch network 50 and the second switch network 54 to adjust the state of the electronic system from the state shown in FIG. 7A to the state shown in FIG. 8.

FIG. 9 is a schematic diagram illustrating the electronic system of 7A configured in a different state than in FIG. 7A. In FIG. 9, the coupled line of the RF coupler 20a is decoupled from the main line of the RF coupler 20a. Instead of providing an indication of forward power at a forward-coupled output as shown in FIG. 7A or providing an indication of reverse power at a reverse-coupled output as shown in FIG. 8, the electronic system can be configured in a decoupled state as shown in FIG. 9. The decoupled state is a low-insertion-loss mode. In the decoupled state, the coupled line of the RF coupler 20a is decoupled from the main line of the RF coupler 20a in FIG. 9. Accordingly, coupling loss from the RF coupler 20a can be significantly reduced or eliminated in the decoupled state. The insertion loss from the main line of the RF coupler 20a may still be present, however.

The coupled port and the isolated port of the RF coupler 20a can both be electrically isolated from termination-impedance elements in the decoupled state. As illustrated in FIG. 9, the impedance-select switches 61, 62, 63 of the first switch network 50 can decouple the isolated port from the first termination impedance elements 52 and the impedance-select switches 65, 66, 67 of the second switch network 54 can decouple the coupled port from the second termination impedance elements 56 in the decoupled state. As also illustrated in FIG. 9, the mode-select switch 64 in the first switch network 50 can decouple the isolated port from the reverse-coupled output and the mode-select switch 68 of the second switch network 54 can decouple the coupled port from the forward-coupled output in the decoupled state. The control circuit 58 can change states of the switches in the first switch network 50 and the second switch network 54 to decouple the coupled line from the main line in the decoupled state shown in FIG. 9.

FIGS. 10A and 10B are schematic diagrams of example termination-impedance elements that can implement the functionality of the first termination-impedance elements 52 and/or the second termination-impedance elements 56 of FIGS. 7A, 8, and 9. A termination impedance can provide an impedance-matching function in the RF coupler to increase power transfer and reduce signal reflection. The termination impedance can be provided between a port of the RF coupler, such as one of a coupled port or an isolated port, and a reference potential, such as ground. The termination impedance can be implemented by any suitable passive impedance element or any suitable series and/or parallel combination of passive impedance elements.

As shown in FIG. 10A, termination-impedance elements can be implemented by an adjustable resistance circuit, an adjustable capacitance circuit, and an adjustable inductance circuit. Switches of a switch network can selectively electrically couple these elements to the coupled terminal and/or the isolated terminal of an RF coupler. Adjusting the impedance of one or more of the adjustable resistance circuit, the adjustable capacitance circuit, or the adjustable inductance circuit can achieve a desired directivity of an RF coupler. In some other examples, one or two of the adjustable resistance circuit, the adjustable capacitance circuit, or the adjustable inductance circuit can be implemented instead of all three.

FIG. 10B is a schematic diagram illustrating that the first termination impedance elements 52 and/or the second termination impedance elements 56 of FIGS. 7A, 8, and 9 can include a plurality of resistors that are electrically coupled to switches of a switch network. Each of the resistors can have a resistance selected to optimize a directivity of an RF coupler for a particular amount of capacitive coupling. Alternatively or additionally, a combination of resistances of these resistors can optimize directivity of an RF coupler for a particular amount of capacitive coupling.

Accordingly, in some examples, a termination impedance of a coupler may be varied based on an amount of capacitive coupling to optimize a directivity of the coupler. Additional methods and systems for adjusting parameters of a coupler to optimize or otherwise influence properties of a coupler based at least in part on an amount of capacitive coupling and/or a frequency of operation of the coupler can be found in U.S. Pat. No. 9,614,269, which is hereby incorporated by reference in its entirety.

Furthermore, although certain configurations of components are provided, alternate configurations are within the scope of the disclosure. For example, the coupler 300 may include one or more additional capacitive, inductor, and/or resistive components coupled in series, parallel, or a combination of both, with one or both of the capacitive elements 314, 316. Elements may be switchably coupled to one or both of the capacitive elements 314, 316 such that an amount of resistance, inductance, and/or capacitance in the coupler 300 may be varied. Similar principles may apply to the coupler 600. Accordingly, it is to be appreciated that other examples of a variable coupling (including, for example, resistive, inductive, and/or capacitive coupling) between a main line and a coupled line are within the scope of the disclosure.

Although the coupler 300 includes switching elements 318-324 in some examples, and the coupler 600 includes the switching elements 616, 618 in some examples, the couplers 300, 600 may include fewer switching elements in other examples. For example, the first capacitive element 314 may be coupled to one of the switching elements 318, 320, and the other switching element may be replaced by a short circuit, such that only one of the switching elements 318, 320 is coupled between the lines 310, 312 and controls a switchable coupling of the first capacitive element 314 between the lines 310, 312. Similar principles apply to the switching elements 322, 324 such that one of the switching elements 322, 324 may be replaced with a short circuit in some examples. Similarly, one of the switching elements 616, 618 may be replaced with a short circuit in some examples.

Accordingly, in some examples a switchable element (for example, a switchable capacitive element) may be switchably coupled between the main and coupled lines of a coupler. In other examples, switchable elements (including, for example, capacitive, resistive, and/or inductive elements) may be switchably coupled between the main and coupled lines of a coupler, or between other portions of the coupler. For example, switchable elements may be switchably coupled to and/or between the coupled port and the isolated port of a coupler in some examples.

Switchably coupling elements between the coupled and isolated ports of a coupler may enable a filter response to be selectively provided by coupling or decoupling the elements between the ports. Such switchable coupling elements may enable a main line of a coupler to be decoupled from a coupled line of the coupler, for example, at desired frequencies of an input signal received by the coupler. Decoupling the coupled and main lines of the coupler may enable an insertion loss to be advantageously reduced at desired frequencies. Accordingly, such switchable coupling elements may provide a frequency-dependent filter response such as a low-pass filter response, a high-pass filter response, a band-pass filter response, and so forth.

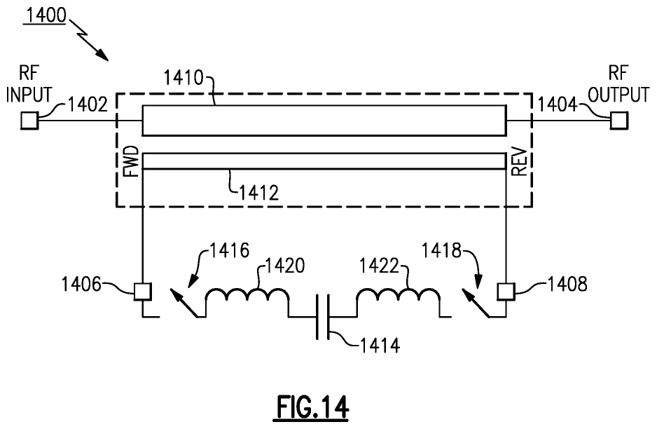

FIG. 11 illustrates a schematic diagram of a coupler 1100 according to an example. The coupler 1100 includes an input port 1102, an output port 1104, a coupled port 1106, an isolated port 1108, a main line 1110, a coupled line 1112, a capacitive element 1114, a first switching element 1116, and a second switching element 1118. The input port 1102 may be substantially similar to the input port 302. The output port 1104 may be substantially similar to the output port 304. The coupled port 1106 may be substantially similar to the coupled port 306. The isolated port 1108 may be substantially similar to the isolated port 308. The main line 1110 may be substantially similar to the transmission line 310. The coupled line 1112 may be substantially similar to the transmission line 312.

The capacitive element 1114 includes a first connection coupled to the first switching element 1116 and a second connection coupled to the second switching element 1118. The first switching element 1116 includes a first connection coupled to the coupled port 1106 and a second connection coupled to the capacitive element 1114. The second switching element 1118 includes a first connection coupled to the capacitive element 1114 and a second connection coupled to the isolated port 1108.

The first switching element 1116 may switchably couple the coupled port 1106 to the capacitive element 1114. The second switching element 1118 may switchably couple the capacitive element 1114 to the isolated port 1108. Each of the switching elements 1116, 1118 may be switchable dependent on one another in other examples. For example, the switching elements 1116, 1118 may be switched together as a pair in some examples. In other examples, the switching elements 1116, 1118 may be switched independently. Furthermore, in some examples, one of the switching elements 1116, 1118 may be omitted and replaced by a short circuit such that only a remaining one of the switching elements 1116, 1118 switchably electrically couples the capacitive element 1114 between the ports 1106, 1108.

The switching elements 1116, 1118 may be switchably controlled to control a capacitive coupling between the coupled port 1106 and the isolated port 1108. A switching state of each of the switching elements 1116, 1118 may be controlled by providing signals (for example, bias-control signals) to respective control terminals of the switching elements 1116, 1118. In various examples, the coupler 1100 may include, or be coupled to, control circuitry to provide control signals to a respective control terminal of each of the switching elements 1116, 1118. For example, the switching elements 1116, 1118 may include MOSFETs each having a gate connection to receive one or more control signals from the control circuitry.

A switching state of the switching elements 1116, 1118 may be controlled based on a frequency of a signal on the main line 1110. The switching elements 1116, 1118 may switchably connect the capacitive element 1114 between the ports 1106, 1108 at, above, or below certain frequencies of the signal, and switchably disconnect the capacitive element 1114 from one or both of the ports 1106, 1108 at, above, or below other frequencies of the signal. In one example, the capacitive element 1114 may be switchably connected between the ports 1106, 1108 above a threshold frequency, and may be switchably disconnected from one or both of the ports 1106, 1108 below the threshold frequency, such that an insertion loss of the coupler 1100 is reduced at higher frequencies as discussed below with respect to FIGS. 12 and 13.

FIG. 12 illustrates a graph 1200 of an insertion loss as a function of frequency according to an example. The y-axis 1202 indicates an insertion loss measured in dB. For example, the y-axis 1202 may indicate an insertion loss at the input port 1102. The x-axis 1204 indicates a frequency measured in GHz. For example, the x-axis 1204 may indicate a frequency of a signal conducted on the main line 1110. The graph 1200 includes a first trace 1206 and a second trace 1208. The first trace 1206 may indicate an insertion loss where the capacitive element 1114 switchably connects the lines 1106, 1108. The second trace 1208 may indicate an insertion loss where the capacitive element 1114 does not switchably connect the lines 1106, 1108.

As indicated by the traces 1206, 1208, the insertion loss increases as frequency increases. However, at higher frequencies (for example, frequencies above approximately 4 GHz), an insertion loss may be lower in examples in which the capacitive element 1114 is switchably connected between the ports 1106, 1108 as indicated by the traces 1206, 1208. It may be desirable to reduce the insertion loss. Accordingly, it may be advantageous to switchably couple the capacitive element 1114 between the ports 1106, 1108 for frequencies at which the capacitive element 1114 reduces an insertion loss of the coupler 1100, and to switchably decouple the capacitive element 1114 from one or both of the ports 1106, 1108 for frequencies at which the capacitive element 1114 increases an insertion loss of the coupler 1100.

FIG. 13 illustrates a graph 1300 of a coupling factor as a function of frequency according to an example. A y-axis 1302 indicates a coupling factor measured in dB. For example, the y-axis 1302 may indicate a coupling factor between the lines 1110, 1112. An x-axis 1304 indicates a frequency measured in GHz. For example, the x-axis 1304 may indicate a frequency of a signal conducted on the main line 1110. The graph 1300 includes a first trace 1306 and a second trace 1308. The first trace 1306 may indicate a coupling factor where the capacitive element 1114 switchably connects the ports 1106, 1108. The second trace 1308 may indicate a coupling factor where the capacitive element 1114 does not switchably connect the ports 1106, 1108.

As indicated by the traces 1306, 1308, the coupling factor decreases as frequency increases. At frequencies above approximately 2.5 GHz, the coupling factor is greater where the capacitive element 1114 is switchably coupled between the ports 1106, 1108, as indicated by the traces 1306, 1308. Accordingly, it may be desirable to switchably connect and disconnect the capacitive element 1114 between the ports 1106, 1108 as desired based on a desired coupling factor. The elements 1114-1118 therefore provide a frequency-dependent filter response as desired to modulate the coupling factor.

FIG. 14 illustrates a schematic diagram of a coupler 1400 according to an example. The coupler 1400 includes an input port 1402, an output port 1404, a coupled port 1406, an isolated port 1408, a main line 1410, a coupled line 1412, a capacitive element 1414, a first switching element 1416, a second switching element 1418, a first inductive element 1420, and a second inductive element 1422. The coupler 1400 may be substantially similar to the coupler 1100, and the elements 1402-1418 may be substantially similar to the elements 1102-1118, respectively. Additionally, the coupler 1400 includes the first inductive element 1420 and the second inductive element 1422.

The first switching element 1416 includes a first connection coupled to the coupled port 1406 and a second connection coupled to the first inductive element 1420. The first inductive element 1420 includes a first connection coupled to the first switching element 1416 and a second connection coupled to the capacitive element 1414. The capacitive element 1414 includes a first connection coupled to the first inductive element 1420 and a second connection coupled to the second inductive element 1422. The second inductive element 1422 includes a first connection coupled to the capacitive element 1414 and a second connection coupled to the second switching element 1418. The second switching element 1418 includes a first connection coupled to the second inductive element 1422 and a second connection coupled to the isolated port 1408.

The inductive elements 1420, 1422 and capacitive element 1414 provide a switchable filter between the ports 1406, 1408. Including the inductive elements 1420, 1422 in series with the capacitive element 1414 may provide a different frequency response than, for example, the capacitive element 1114 alone. For example, the inductive elements 1420, 1422 may reject higher-frequency signals and thus reduce a coupling factor at higher frequencies. Accordingly, the inductive elements 1420, 1422 may be included in examples in which such a frequency response is desirable.

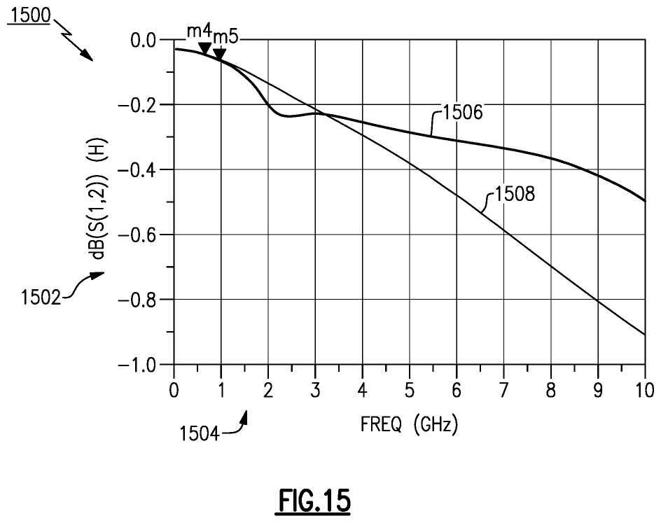

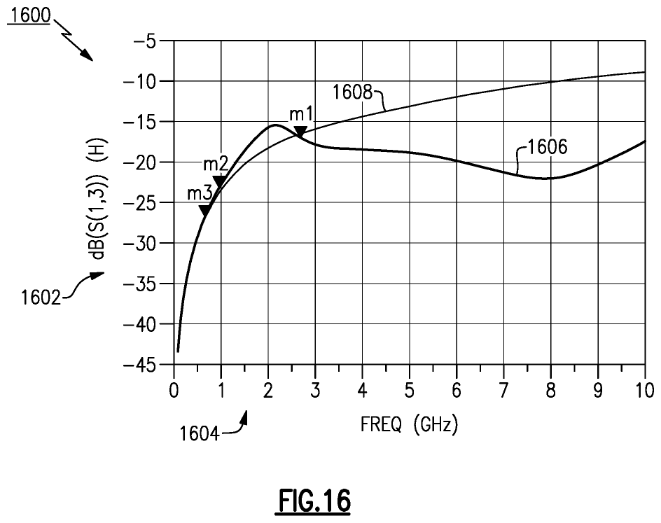

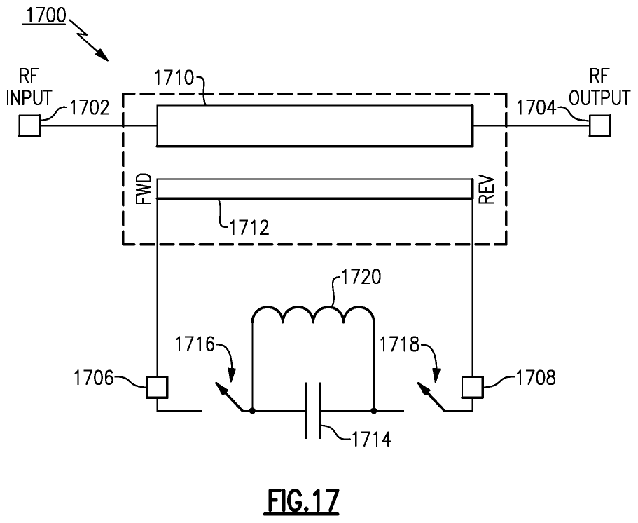

FIG. 15 illustrates a graph 1500 of an insertion loss as a function of frequency according to an example. The y-axis 1502 indicates an insertion loss measured in dB. For example, the y-axis 1502 may indicate an insertion loss at the input port 1402. The x-axis 1504 indicates a frequency measured in GHz. For example, the x-axis 1504 may indicate a frequency of a signal conducted in the main line 1410. The graph 1500 includes a first trace 1506 and a second trace 1508. The first trace 1506 may indicate an insertion loss where the capacitive element 1414 and inductive elements 1420, 1422, coupled in series with one another, switchably connect the lines 1406, 1408. The second trace 1508 may indicate an insertion loss where the capacitive element 1414 and inductive elements 1420, 1422 do not switchably connect the lines 1406, 1408.

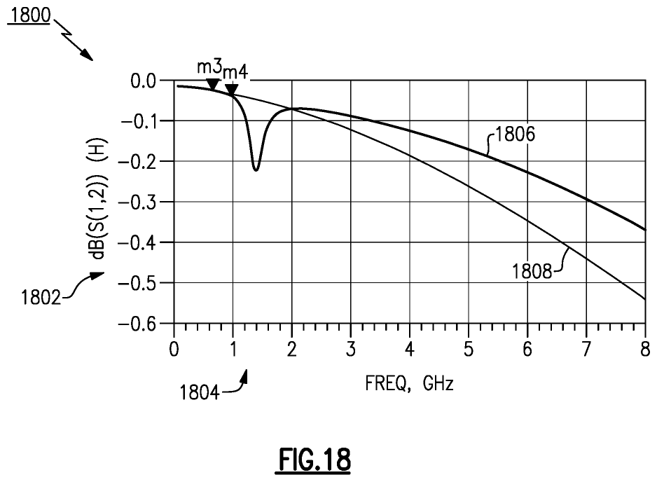

FIG. 16 illustrates a graph 1600 of a coupling factor as a function of frequency according to an example. A y-axis 1602 indicates a coupling factor measured in dB. For example, the y-axis 1602 may indicate a coupling factor between the lines 1410, 1412. An x-axis 1604 indicates a frequency measured in GHz. For example, the x-axis 1604 may indicate a frequency of a signal conducted in the main line 1410. The graph 1600 includes a first trace 1606 and a second trace 1608. The first trace 1606 may indicate a coupling factor where the capacitive element 1414 and the inductive elements 1420, 1422 switchably connect the ports 1406, 1408. The second trace 1608 may indicate a coupling factor where the capacitive element 1414 and the inductive elements 1420, 1422 do not switchably connect the ports 1406, 1408.

As indicated by the differing traces 1206, 1506, the insertion loss of the coupler 1400 as a function of frequency differs from the insertion loss of the coupler 1100 as a function of frequency due at least in part to the addition of the inductive elements 1420, 1422. Similarly, as indicated by the differing traces 1306, 1606, the coupling factor of the coupler 1400 as a function of frequency differs from the coupling factor of the coupler 1100 as a function of frequency due at least in part to the addition of the inductive elements 1420, 1422. Accordingly, a type and arrangement of components switchably couplable between a coupled port and isolated port may be selected based at least in part on an application of a coupler. For example, the coupler 1400 may be more desirable than the coupler 1100 for certain applications (for example, for certain operating frequencies), and the coupler 1100 may be more desirable than the coupler 1400 for other applications (for example, for other operating frequencies) based at least in part on a desired coupling factor and insertion loss at particular operating frequencies. In other examples, other types and arrangements of components coupled to a coupled and/or isolation port may be implemented.

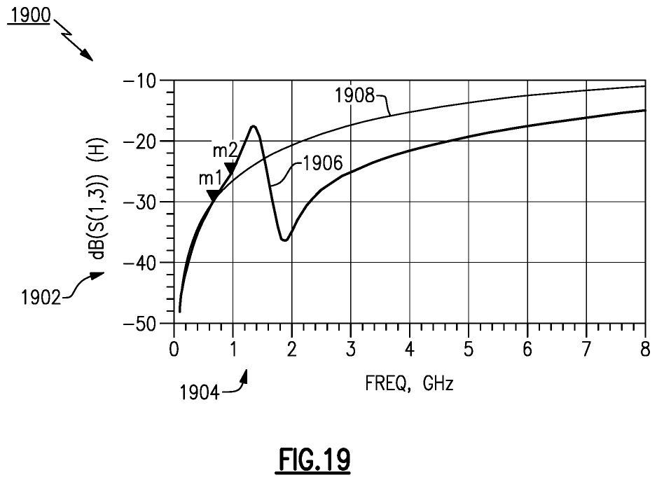

For example, FIG. 17 illustrates a schematic diagram of a coupler 1700 according to another example. The coupler 1700 includes an input port 1702, an output port 1704, a coupled port 1706, an isolated port 1708, a main line 1710, a coupled line 1712, a capacitive element 1714, a first switching element 1716, a second switching element 1718, and an inductive element 1720. The coupler 1700 may be substantially similar to the coupler 1100, and the elements 1702-1718 may be substantially similar to the elements 1102-1118, respectively. Additionally, the coupler 1700 includes the inductive element 1720.

The first switching element 1716 includes a first connection coupled to the coupled port 1706 and a second connection coupled to the capacitive element 1714 and the inductive element 1720. The inductive element 1720 includes a first connection coupled to the first switching element 1716 and a second connection coupled to the second switching element 1718, and is coupled in parallel with the capacitive element 1714. The capacitive element 1714 includes a first connection coupled to the first switching element 1716 and a second connection coupled to the second switching element 1718, and is coupled in parallel with the inductive element 1720. The second switching element 1718 includes a first connection coupled to the capacitive element 1714 and the inductive element 1720, and a second connection coupled to the isolated port 1708.

The inductive element 1720 and capacitive element 1714 provide a switchable filter between the ports 1706, 1708. Including the inductive element 1720 in parallel with the capacitive element 1714 may provide a different frequency response than, for example, the capacitive element 1714 alone or in series with the inductive element 1720. Accordingly, the inductive element 1720 may be included in examples in which such a frequency response is desirable.

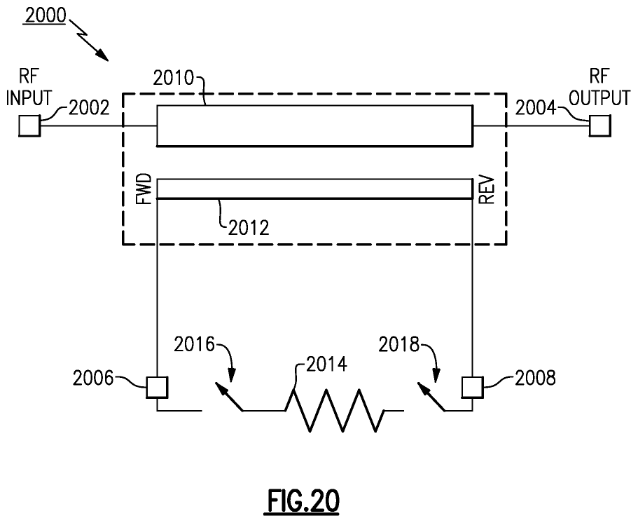

FIG. 18 illustrates a graph 1800 of an insertion loss as a function of frequency according to an example. The y-axis 1802 indicates an insertion loss measured in dB. For example, the y-axis 1802 may indicate an insertion loss at the input port 1702. The x-axis 1804 indicates a frequency measured in GHz. For example, the x-axis 1804 may indicate a frequency of a signal conducted in the main line 1710. The graph 1800 includes a first trace 1806 and a second trace 1808. The first trace 1806 may indicate an insertion loss where the capacitive element 1714 and the inductive element 1720, coupled in parallel with one another, switchably connect the lines 1706, 1708. The second trace 1808 may indicate an insertion loss where the capacitive element 1714 and the inductive element 1720 do not switchably connect the lines 1706, 1708.

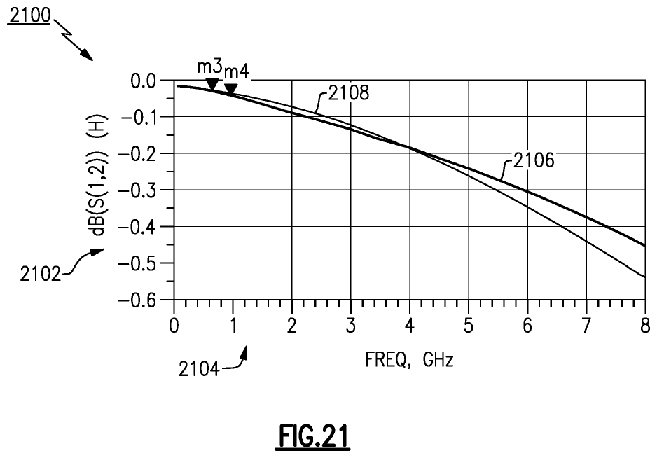

FIG. 19 illustrates a graph 1900 of a coupling factor as a function of frequency according to an example. A y-axis 1902 indicates a coupling factor measured in dB. For example, the y-axis 1902 may indicate a coupling factor between the lines 1710, 1712. An x-axis 1904 indicates a frequency measured in GHz. For example, the x-axis 1904 may indicate a frequency of a signal conducted in the main line 1710. The graph 1900 includes a first trace 1906 and a second trace 1908. The first trace 1906 may indicate a coupling factor where the capacitive element 1714 and the inductive element 1720 switchably connect the ports 1706, 1708. The second trace 1908 may indicate a coupling factor where the capacitive element 1714 and the inductive element 1720 do not switchably connect the ports 1706, 1708.

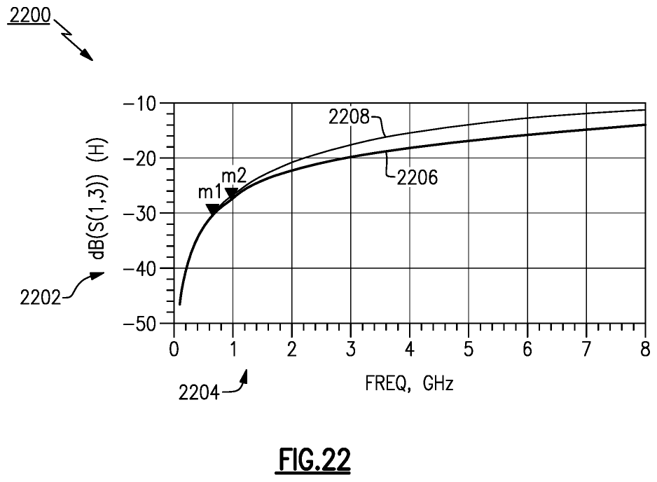

FIG. 20 illustrates a schematic diagram of a coupler 2000 according to another example. The coupler 2000 includes an input port 2002, an output port 2004, a coupled port 2006, an isolated port 2008, a main line 2010, a coupled line 2012, a resistive element 2014, a first switching element 2016, and a second switching element 2018. The coupler 2000 may be substantially similar to the coupler 1100, and the elements 2002-2012, 2016, 2018 may be substantially similar to the elements 1102-1112, 1116, 1118, respectively. Additionally, the coupler 2000 includes the resistive element 2014.

The first switching element 2016 includes a first connection coupled to the coupled port 2006 and a second connection coupled to the resistive element 2014. The resistive element 2014 includes a first connection coupled to the first switching element 2016 and a second connection coupled to the second switching element 2018. The second switching element 2018 includes a first connection coupled to the resistive element 2014 and a second connection coupled to the isolated port 2008.

The resistive element 2014 provides a switchable filter between the ports 2006, 2008. Including the resistive element 2014 may provide a different frequency response than, for example, a capacitive element alone or in series or parallel with at least one inductive element. Accordingly, the resistive element 2014 may be included in examples in which such a frequency response is desirable.

FIG. 21 illustrates a graph 2100 of an insertion loss as a function of frequency according to an example. The y-axis 2102 indicates an insertion loss measured in dB. For example, the y-axis 2102 may indicate an insertion loss at the input port 2002. The x-axis 2104 indicates a frequency measured in GHz. For example, the x-axis 2104 may indicate a frequency of a signal conducted in the main line 2010. The graph 2100 includes a first trace 2106 and a second trace 2108. The first trace 2106 may indicate an insertion loss where the resistive element 2014 switchably connects the lines 2006, 2008. The second trace 2108 may indicate an insertion loss where the resistive element 2014 does not switchably connect the lines 2006, 2008.

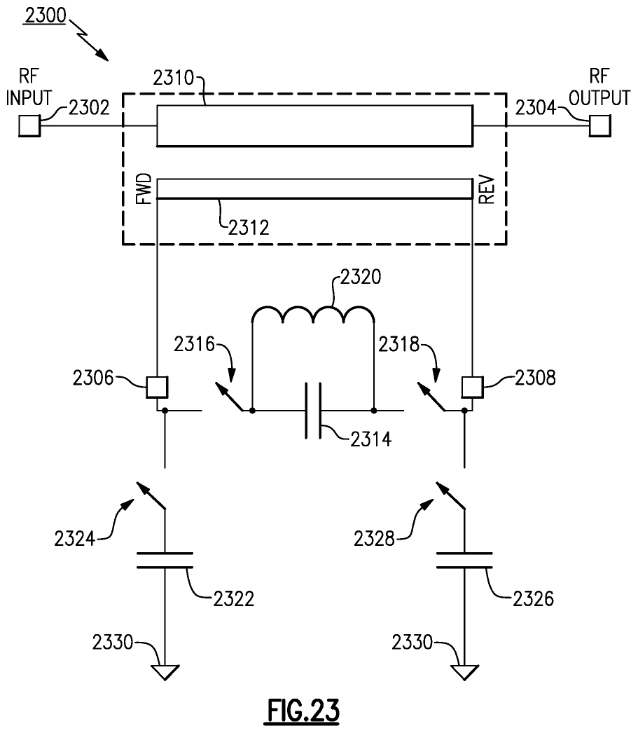

FIG. 22 illustrates a graph 2200 of a coupling factor as a function of frequency according to an example. A y-axis 2202 indicates a coupling factor measured in dB. For example, the y-axis 2202 may indicate a coupling factor between the lines 2010, 2012. An x-axis 2204 indicates a frequency measured in GHz. For example, the x-axis 2204 may indicate a frequency of a signal conducted in the main line 2010. The graph 2200 includes a first trace 2206 and a second trace 2208. The first trace 2206 may indicate a coupling factor where the resistive element 2014 switchably connect the ports 2006, 2008. The second trace 2208 may indicate a coupling factor where the resistive element 2014 does not switchably connect the ports 2006, 2008.

Accordingly, a frequency response of a coupler may be controlled by switchably coupling one or more resistive, inductive, and/or capacitive elements between a coupled port and an isolated port of a coupler. Certain example arrangements have been discussed above, but other arrangements of one or more resistive, inductive, and/or capacitive elements, individually or in combination, may be coupled in series and/or parallel with one another and switchably coupled between the coupled and isolated ports. Furthermore, in some examples, each of one or more elements may be switchably coupled to only one of the coupled port or isolated port, including capacitive elements, resistive elements, and/or inductive elements.

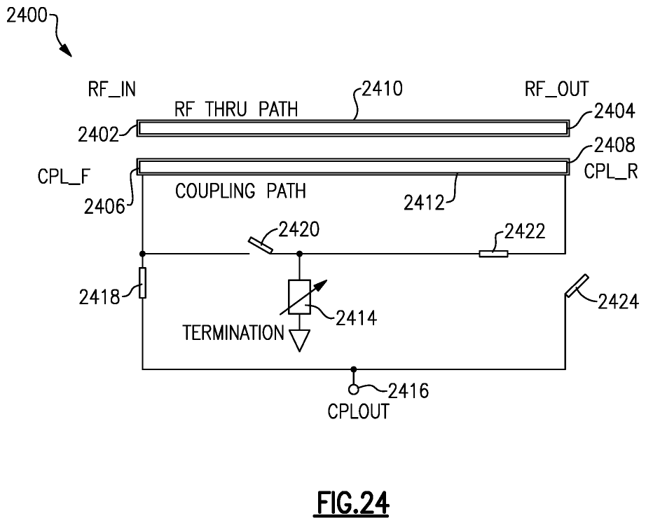

For example, FIG. 23 illustrates a schematic diagram of a coupler 2300 according to another example. The coupler 2300 includes an input port 2302, an output port 2304, a coupled port 2306, an isolated port 2308, a main line 2310, a coupled line 2312, a first capacitive element 2314, a first switching element 2316, a second switching element 2318, an inductive element 2320, a second capacitive element 2322, a third switching element 2324, a third capacitive element 2326, and a fourth switching element 2328. The coupler 2300 may be substantially similar to the coupler 1700, and the elements 2302-2320 may be substantially similar to the elements 1702-1720, respectively. Additionally, the coupler 2300 includes the second capacitive element 2322, the third switching element 2324, the third capacitive element 2326, and the fourth switching element 2328.

The first switching element 2316 includes a first connection coupled to the coupled port 2306 and a second connection coupled to the capacitive element 2314 and the inductive element 2320. The inductive element 2320 includes a first connection coupled to the first switching element 2316 and a second connection coupled to the second switching element 2318, and is coupled in parallel with the capacitive element 2314. The capacitive element 2314 includes a first connection coupled to the first switching element 2316 and a second connection coupled to the second switching element 2318, and is coupled in parallel with the inductive element 2320. The second switching element 2318 includes a first connection coupled to the capacitive element 2314 and the inductive element 2320, and a second connection coupled to the isolated port 2308.

The second capacitive element 2322 includes a first connection coupled to the third switching element 2324 and a second connection coupled to a reference node 2330 (for example, a neutral node). The third switching element 2324 includes a first connection coupled to the coupled port 2306 and a second connection coupled to the second capacitive element 2322. The third capacitive element 2326 includes a first connection coupled to the fourth switching element 2328 and a second connection coupled to the reference node 2330. The fourth switching element 2328 includes a first connection coupled to the isolated port 2308 and a second connection coupled to the third capacitive element 2326.

The first capacitive element 2314, inductive element 2320, second capacitive element 2322, and third capacitive element 2326 provide a switchable filter to the ports 2306, 2308. Including the capacitive elements 2322, 2326 in addition to the inductive element 2320 in parallel with the capacitive element 2314 may provide a different frequency response than, for example, the capacitive element 2314 in parallel with the inductive element 2320, similar to the example provided above with respect to the coupler 1700. Accordingly, the capacitive elements 2322, 2326 may be included in examples in which such a frequency response is desirable.

Accordingly, principles of the disclosure are applicable not only to various arrangements of one or more resistive, inductive, and/or capacitive elements switchably coupled between the coupled and isolated ports, but also to arrangements of such elements in which at least one element is coupled to one, but not both, of the coupled and isolated ports. In some examples, similar or identical components may be coupled to both the coupled and isolated ports, that is, elements coupled to the coupled port may be symmetrical to elements coupled to the isolated port. In other examples, a type and/or number of components coupled to the coupled and isolated ports may differ, that is, the elements coupled to the coupled port may be asymmetrical with respect to elements coupled to the isolated port.

In various examples, each of the coupled port and the isolated port may be coupled to a respective switching element, and one or more resistive, inductive, and/or capacitive elements may be coupled between the switching elements, such that two switching elements are coupled in series between the coupled and isolated ports. In other examples, one of the switching elements may be removed such that only one switching element is provided in series between the coupled and isolated ports. For example, using the coupler 1100 as an example, one of the switching elements 1116, 1118 may be removed and replaced with a short circuit, and a remaining one of the switching elements 1116, 1118 may switchably electrically couple or decouple the capacitive element 1114 between the ports 1106, 1108.

In some examples, one or more switching elements may switchably couple or decouple fewer than all of several resistive, inductive, and/or capacitive elements between the coupled port and isolated port. For example, in an arrangement in which a capacitive element is coupled in parallel with an inductive element, a first switch may be coupled in series with the capacitive element and a second switch may be coupled in series with the inductive element. In a variation of this example, one of the first switch and the second switch may be omitted such that one of the elements is coupled between the coupled port and isolated port, and the other of the elements is switchably coupled between the coupled port and the isolated port. In other examples, other combinations and arrangements of switching elements may be implemented.

In various examples, a directivity of a coupler may be affected by various conditions or circumstances, such as coupling and/or decoupling elements from one or more ports of a coupler, as discussed above. In some examples, a switchable termination impedance may be implemented. For example, a switchable termination impedance may be implemented in connection with one or more switching devices configured to switchably couple and/or decouple the switchable termination impedance to one or both of a coupled and isolated port of a coupler.

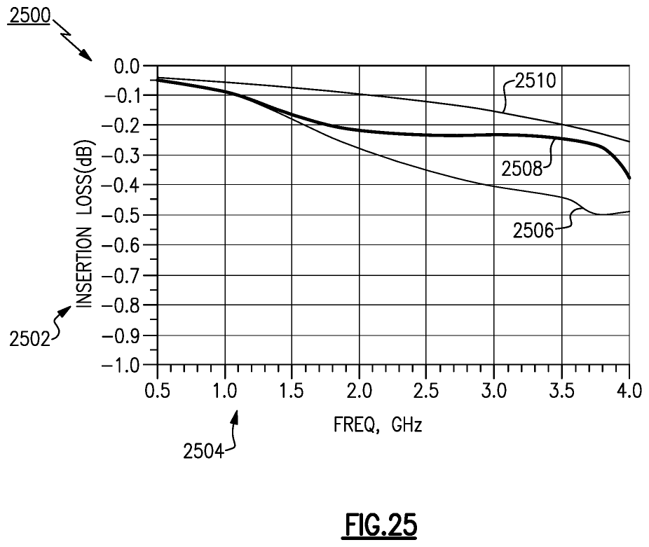

FIG. 24 illustrates a schematic diagram of a coupler 2400 according to an example. The coupler 2400 includes an input port 2402, an output port 2404, a coupled port 2406, an isolated port 2408, a main line 2410, a coupled line 2412, a switchable termination impedance 2414, an output coupled port 2416, a first switching element 2418, a second switching element 2420, a third switching element 2422, and a fourth switching element 2424.

Each of the coupled port 2406 and the isolated port 2408 may be switchably coupled to either of the switchable termination impedance 2414 and the output coupled port 2416 via the switching elements 2418-2424. For example, the first switching element 2418 and the third switching element 2422 may be controlled to be closed and conducting and the second switching element 2420 and the fourth switching element 2424 may be controlled to be open and non-conducting to couple the coupled port 2406 to the output coupled port 2416 and to couple the isolated port 2408 to the switchable termination impedance 2416. Similarly, the first switching element 2418 and the third switching element 2422 may be controlled to be open and non-conducting and the second switching element 2420 and the fourth switching element 2424 may be controlled to be closed and conducting to couple the coupled port 2406 to the switchable termination impedance 2416 and to couple the isolated port 2408 to the output coupled pot 2416.

An impedance of the switchable termination impedance 2416 may be selectively controlled to implement a desired termination impedance and, consequently, a desired insertion loss and/or coupling-factor loss. For example, in a carrier-aggregation (CA) application, a low insertion loss may be desired at low and high frequencies, and the coupler 2400 may be controlled accordingly.

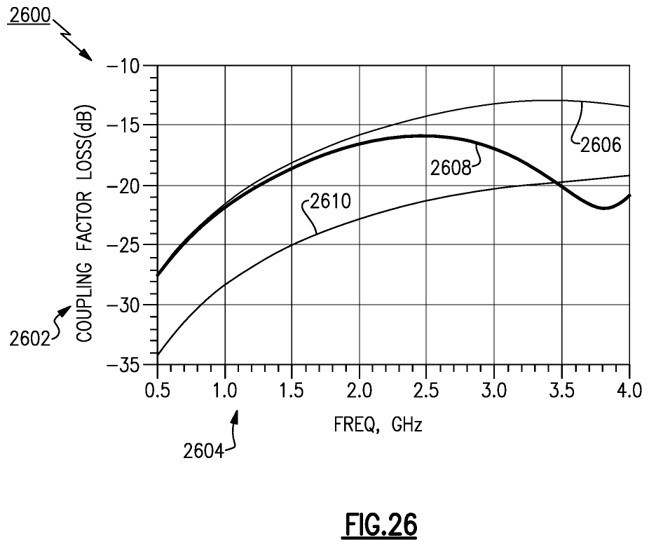

FIG. 25 illustrates a graph 2500 of an insertion loss as a function of frequency according to an example. The y-axis 2502 indicates an insertion loss measured in dB. The x-axis 2504 indicates a frequency measured in GHz. The graph 2500 includes a first trace 2506, a second trace 2508, and a third trace 2510. The first trace 2506 may indicate an insertion loss of the coupler 2400 according to one example.

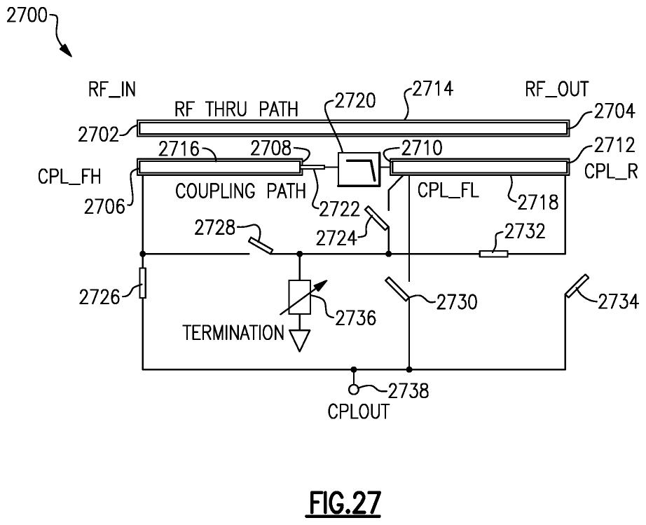

FIG. 26 illustrates a graph 2600 of a coupling-factor loss as a function of frequency according to an example. The y-axis 2602 indicates a coupling-factor loss measured in dB. The x-axis 2604 indicates a frequency measured in GHz. The graph 2600 includes a first trace 2606, a second trace 2608, and a third trace 2610. The first trace 2606 may indicate a coupling-factor loss of the coupler 2400 according to one example.

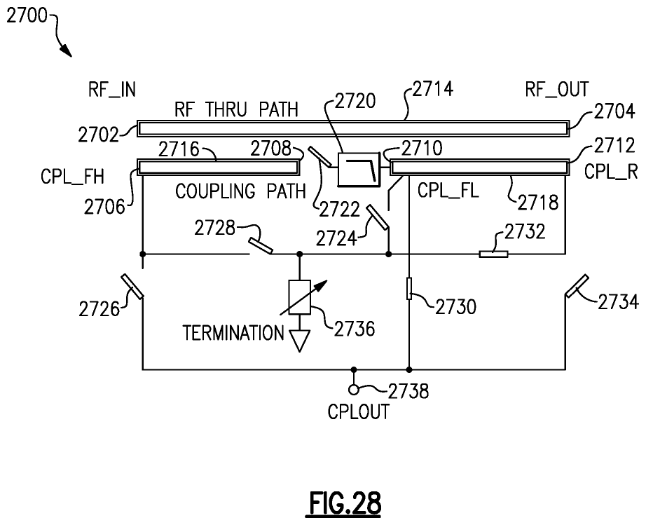

In some examples, a coupler similar to the coupler 2400 may be implemented having a switchable coupled line. For example, a coupled line may have multiple sections configured to be coupled or decoupled from other components of a coupler. FIG. 27 illustrates a schematic diagram of a coupler 2700 according to an example. The coupler 2700 includes an input port 2702, an output port 2704, a first coupled port 2706, a coupling switching port 2708, a second coupled port 2710, an isolation port 2712, a main line 2714, a first coupled-line section 2716, a second coupled-line section 2718, a low-pass filter 2720, a first switching element 2722, a second switching element 2724, a third switching element 2726, a fourth switching element 2728, a fifth switching element 2730, a sixth switching element 2732, a seventh switching element 2734, a switchable termination impedance 2736, and a coupled output port 2738.

The first switching element 2722 is coupled between the first coupled-line section 2716 and the low-pass filter 2720. The low-pass filter 2720 is coupled between the first switching element 2722 and the second coupled-line section 2718. The second switching element 2724 is connected between the second coupled-line section 2718 and the switchable termination impedance 2736. The third switching element 2726 is coupled between the first coupled-line section 2716 and the coupled output port 2738. The fourth switching element 2728 is coupled between the first coupled-line section 2716 and the switchable termination impedance 2736. The fifth switching element 2730 is coupled between the second coupled-line section 2718 and the coupled output port 2738. The sixth switching element 2732 is coupled between the second coupled-line section 2718 and the switchable termination impedance 2736. The seventh switching element 2734 is coupled between the second coupled-line section 2718 and the coupled output port 2738.

The switching elements 2722-2734 are configured to switchably couple the coupled-line sections 2716, 2718 to either of the coupled output port 2738 and the switchable termination impedance 2736. For example, the third switching element 2726 is configured to switchably couple the first coupled port 2706 to the coupled output port 2738, and the fourth switching element 2728 is configured to switchably couple the coupled port 2706 to the switchable termination impedance 2736. In various examples, the third switching element 2726 and the fourth switching element 2728 may not be in a closed state simultaneously.

In another example, the second switching element 2724 is configured to switchably couple the second coupled port 2710 to the switchable termination impedance 2736, and the fifth switching element 2730 is configured to switchably couple the second coupled port 2710 to the coupled output port 2738. In various examples, the second switching element 2724 and the fifth switching element 2730 may not be in a closed state simultaneously.

In another example, the sixth switching element 2732 is configured to switchably couple the isolation port 2712 to the switchable termination impedance 2736, and the seventh switching element 2734 is configured to switchably couple the isolation port 2712 to the coupled output port 2738. In various examples, the sixth switching element 2732 and the seventh switching element 2734 may not be in a closed state simultaneously.

As illustrated in FIG. 27, the switching elements 2722, 2726, and 2732 may be controlled to be in a closed and conducting state, and the remaining switching elements 2724, 2728, 2730, and 2734 may be controlled to be in an open and non-conducting state, such that the first coupled port 2706 is coupled to the coupled output port 2738 via the third switching element 2726, the isolation port 2712 is coupled to the switchable termination impedance 2736 via the sixth switching element 2732, and the coupling switching port 2708 is coupled to the second coupled port 2710 via the first switching element 2722 and the low-pass filter 2720.

Accordingly, the coupler 2700 in the configuration of FIG. 27 may be similar to the coupler 2400 in the configuration illustrated in FIG. 24, at least except that the coupler 2700 includes two coupled-line sections 2716, 2718 coupled via the low-pass filter 2720. The coupler 2700 may exhibit an improved coupling factor and/or insertion loss, particularly at higher frequencies at which the low-pass filter 2720 appreciably attenuates a signal passing therethrough. For example, in FIGS. 25 and 26, the second traces 2508, 2608 may correspond to an insertion loss and a coupling-factor loss, respectively, of the coupler 2700 in the configuration of FIG. 27. As illustrated by FIGS. 25 and 26, the coupler 2700 in the configuration of FIG. 27 may exhibit a more desirable insertion loss and/or coupling-factor loss at certain operating frequencies.

In another example illustrated in FIG. 28, the switching elements 2722-2728 and 2734 may be controlled to be in an open and non-conducting state and the switching elements 2730 and 2732 may be controlled to be in a closed and conducting state, such that the second coupled port 2710 is coupled to the coupled output port 2738 via the fifth switching element 2730 and the isolation port 2712 is coupled to the switchable termination impedance 2736 via the sixth switching element 2732. The configuration of the coupler 2700 in FIG. 28 may exhibit an improved coupling factor and/or insertion loss relative to other configurations, particularly at low-to-mid-band frequencies and upper-band frequencies. For example, in FIGS. 25 and 26, the third traces 2510, 2610 may correspond to an insertion loss and a coupling-factor loss, respectively, of the coupler 2700 in the configuration of FIG. 28. As illustrated by FIGS. 25 and 26, the coupler 2700 in the configuration of FIG. 28 may exhibit a more desirable insertion loss and/or coupling-factor loss at certain operating frequencies.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A coupler comprising:
an input port;
an output port;
a coupled port;
an isolated port;
a main line coupled between the input port and the output port;
a coupled line coupled between the coupled port and the isolated port; and
at least one capacitive element switchably coupled between at least one of the input port or the main line and at least one of the coupled port or the coupled line.

2. The coupler of claim 1 wherein the at least one capacitive element includes a first capacitor having a first connection coupled to the input port and a second connection coupled to the coupled port.

3. The coupler of claim 2 wherein the at least one capacitive element includes a second capacitor having a first connection coupled to the output port and a second connection coupled to the isolated port.

4. The coupler of claim 3 further comprising at least one switching element configured to switchably disconnect at least one of the first capacitor or the second capacitor from at least one of the input port, the output port, the coupled port, or the isolated port.

5. The coupler of claim 4 wherein the at least one switching element includes a first switch coupled between the first capacitor and the input port and a second switch coupled between the first capacitor and the coupled port.

6. The coupler of claim 4 wherein the at least one switching element includes a first switch coupled between the second capacitor and the output port and a second switch coupled between the second capacitor and the isolated port.

7. The coupler of claim 4 further comprising control circuitry configured to control a switching state of the at least one switching element.

8. The coupler of claim 7 wherein the coupler is configured to:
receive an input signal at the input port, the input signal having a signal frequency; and
control the switching state of the at least one switching element based on the signal frequency of the input signal.

9. The coupler of claim 8 wherein the control circuitry is configured to switchably connect the first capacitor and the second capacitor to at least one of the input port, the output port, the coupled port, or the isolated port at a first frequency of the input signal, and is configured to switchably disconnect the first capacitor and the second capacitor from the input port, the output port, the coupled port, and the isolated port at a second frequency of the input signal.

10. The coupler of claim 9 wherein the first frequency is less than the second frequency.

11. The coupler of claim 10 wherein the first frequency is approximately 1 GHz.

12. The coupler of claim 10 wherein the second frequency is approximately 3 GHz.

13. The coupler of claim 1 wherein the at least one capacitive element includes a capacitor having a first connection coupled directly to the main line and a second connection coupled directly to the coupled line.

14. The coupler of claim 13 further comprising at least one switching element configured to switchably disconnect the capacitor from at least one of the main line or the coupled line.

15. The coupler of claim 14 wherein the at least one switching element includes a first switch coupled between the capacitor and the main line and a second switch coupled between the capacitor and the coupled line.

16. The coupler of claim 15 further comprising control circuitry configured to control a switching state of the at least one switching element.

17. The coupler of claim 16 wherein the coupler is configured to:
receive an input signal at the input port, the input signal having a signal frequency; and
control the switching state of the at least one switching element based on the signal frequency of the input signal.

18. The coupler of claim 17 wherein the control circuitry is configured to switchably connect the capacitor to the main line and the coupled line at a first frequency of the input signal, and is configured to switchably disconnect the capacitor from at least one of the main line or the coupled line at a second frequency of the input signal.

19. The coupler of claim 18 wherein the first frequency is less than the second frequency.

20. The coupler of claim 19 wherein the first frequency is approximately 1 GHz.

21. The coupler of claim 19 wherein the second frequency is approximately 3 GHz.
